(19) United States
(12) Patent Application Publication
(10) Pub. No.: US 2025/0386658 A1
(43) Pub. Date: Dec. 18, 2025

(54) LIGHT SENSING PIXEL, DISPLAY PANEL, DISPLAY DEVICE, AND ELECTRONIC DEVICE

(71) Applicant: Samsung Display Co., LTD., Yongin-si, Gyeonggi-do (KR)

(72) Inventors: HYANG-A PARK, Yongin-si (KR); DAE-YOUNG LEE, Yongin-si (KR); TAEKYUNG AHN, Yongin-si (KR); HYUNDAE LEE, Yongin-si (KR); Soo Yeong Hong, Yongin-si (KR)

(21) Appl. No.: 19/068,894

(22) Filed: Mar. 3, 2025

(30) Foreign Application Priority Data
Jun. 13, 2024 (KR) 10-2024-0076888

(51) Int. Cl. H10K 39/00; H04N 25/766; H04N 25/77; H04N 25/78; H10K 39/34; H10K 39/38; H10K 59/131

(52) U.S. Cl. CPC H10K 39/601; H04N 25/766; H04N 25/77; H04N 25/78; H10K 39/34; H10K 39/38; H10K 59/131

(57) ABSTRACT

A light sensing pixel of a display device includes a first organic photodiode; a second organic photodiode; and a sensing pixel circuit configured to perform a light sensing operation using the first organic photodiode in response to a first transfer signal, and to perform a light sensing operation using the second organic photodiode in response to a second transfer signal.

### CROSS-REFERENCE TO RELATED APPLICATION

The present application claims priority to and the benefit of Korean Patent Application No. 10-2024-0076888, filed on Jun. 13, 2024, in the Korean Intellectual Property Office, the entire disclosure of which is incorporated herein by reference.

### BACKGROUND

### 1 Field

Aspects of the present inventive concept relate to a display device.

### 2. Description of the Related Art

Electronic devices (e.g., a smart phone, a smart watch, etc.) have been developed which perform bio-sensing operations, for example, a fingerprint sensing operation, a photoplethysmography (“PPG”) sensing operation, etc. These electronic devices may perform the bio-sensing operations using a sensor that is separate from a display device. In such examples, a size of a display region of the display device may be reduced, and a size of a bezel may be increased.

Attempts have been made to solve this problem. For example, an in-cell light sensor technique has been used which employs an optical sensor or a light sensing pixel within the display region of the display device.

The above information disclosed in this Background section is only for enhancement of understanding of the background of the invention and therefore it may contain information that does not form the prior art.

### SUMMARY

Aspects of some embodiments are directed to a light sensing pixel in which two organic photodiodes are connected to a single sensing pixel circuit.

Aspects of some embodiments are directed to a display panel including a light sensing pixel in which two organic photodiodes are connected to a single sensing pixel circuit.

Aspects of some embodiments are directed to a display device including a light sensing pixel in which two organic photodiodes are connected to a single sensing pixel circuit.

According to some embodiments of the present disclosure, there is provided a light sensing pixel of a display device, the light sensing pixel including: a first organic photodiode; a second organic photodiode; and a sensing pixel circuit configured to perform a light sensing operation using the first organic photodiode in response to a first transfer signal, and to perform a light sensing operation using the second organic photodiode in response to a second transfer signal.

In some embodiments, a length of an anode extension of the first organic photodiode to the sensing pixel circuit is equal to a length of an anode extension of the second organic photodiode to the sensing pixel circuit.

In some embodiments, the first organic photodiode and the second organic photodiode are arranged in different pixel rows and different pixel columns on a display panel of the display device.

In some embodiments, the first organic photodiode and the second organic photodiode are arranged in a same pixel row and different pixel columns on a display panel of the display device.

In some embodiments, the first organic photodiode and the second organic photodiode are arranged in different pixel rows and a same pixel column on a display panel of the display device.

In some embodiments, the sensing pixel circuit includes: a first transistor configured to apply a reset voltage to a gate node in response to a reset signal; a second transistor configured to generate a sensing current based on a voltage of the gate node; a third transistor configured to transfer the sensing current to a readout line in response to a scan signal; a fourth transistor configured to connect an anode of the first organic photodiode to the gate node in response to the first transfer signal; and a fifth transistor configured to connect an anode of the second organic photodiode to the gate node in response to the second transfer signal.

In some embodiments, the first transistor includes a gate configured to receive the reset signal, a first terminal connected to a line configured to transfer the reset voltage, and a second terminal connected to the gate node, the second transistor includes a gate connected to the gate node, a first terminal connected to the line configured to transfer the reference voltage, and a second terminal, and the third transistor includes a gate configured to receive the scan signal, a first terminal connected to the second terminal of the second transistor, and a second terminal connected to the readout line.

In some embodiments, the fourth transistor includes a gate configured to receive the first transfer signal, a first terminal connected to the gate node, and a second terminal connected to the anode of the first organic photodiode, and the fifth transistor includes a gate configured to receive the second transfer signal, a first terminal connected to the gate node, and a second terminal connected to the anode of the second organic photodiode.

In some embodiments, the second and third transistors are P-type metal-oxide-semiconductor (PMOS) transistors, and the first, fourth, and fifth transistors are N-type metal-oxide-semiconductor (NMOS) transistors.

In some embodiments, the first through fifth transistors are NMOS transistors.

In some embodiments, the first through fifth transistors are PMOS transistors.

In some embodiments, a voltage of the anode of the first organic photodiode is reset to the reset voltage in a first frame period, the voltage of the anode of the first organic photodiode is changed according to a light intensity in one or more second frame periods, the sensing current corresponding to the voltage of the anode of the first organic photodiode is output to the readout line in a third frame period, a voltage of the anode of the second organic photodiode is reset to the reset voltage in a fourth frame period, the voltage of the anode of the second organic photodiode is changed according to the light intensity in one or more fifth frame periods, the sensing current corresponding to the voltage of the anode of the first organic photodiode is output to the readout line in a sixth frame period, the first transfer signal is at an active level during the first frame period, the one or more second frame periods and the third frame period, and the second transfer is at an active level during the fourth frame period, the one or more fifth frame periods and the sixth frame period.

According to some embodiments of the present disclosure, there is provided a display panel including: a plurality of light emitting pixels; a plurality of organic photodiodes; and a plurality of sensing pixel circuits, wherein one of the plurality of organic photodiodes is arranged per four light emitting pixels of the plurality of light emitting pixels, and wherein two organic photodiodes of the plurality of organic photodiodes are connected to one sensing pixel circuit of the plurality of sensing pixel circuits.

In some embodiments, anode extensions of the two organic photodiodes connected to the one sensing pixel circuit have a same length to the one sensing pixel circuit.

In some embodiments, the plurality of organic photodiodes includes: a first organic photodiode arranged in a first pixel row and a second pixel column; and a second organic photodiode arranged in a second pixel row and a fourth pixel column, wherein the first organic photodiode and the second organic photodiode are connected to a same one of the plurality of sensing pixel circuits.

In some embodiments, the plurality of sensing pixel circuits connected to the plurality of organic photodiodes arranged in four pixel rows are connected to two scan lines of four scan lines arranged in the four pixel rows.

In some embodiments, the plurality of sensing pixel circuits connected to the plurality of organic photodiodes arranged in four pixel columns are connected to two readout lines.

In some embodiments, the display panel further includes: a multiplexer configured to connect the two readout lines to one sensing channel.

In some embodiments, the plurality of organic photodiodes includes: a first organic photodiode arranged in a first pixel row and a second pixel column; and a second organic photodiode arranged in the first pixel row and a sixth pixel column, and wherein the first organic photodiode and the second organic photodiode are connected to a same one of the plurality of sensing pixel circuits.

In some embodiments, the plurality of sensing pixel circuits connected to the plurality of organic photodiodes arranged in four pixel rows are connected to four scan lines arranged in the four pixel rows.

In some embodiments, the plurality of sensing pixel circuits connected to the plurality of organic photodiodes arranged in four pixel columns are connected to one readout line.

In some embodiments, the plurality of organic photodiodes includes: a first organic photodiode arranged in a first pixel row and a second pixel column; and a second organic photodiode arranged in a third pixel row and the second pixel column, and the first organic photodiode and the second organic photodiode are connected to a same one of the plurality of sensing pixel circuits.

In some embodiments, the plurality of sensing pixel circuits connected to the plurality of organic photodiodes arranged in four pixel rows are connected to one scan line of four scan lines arranged in the four pixel rows.

In some embodiments, the plurality of sensing pixel circuits connected to the plurality of organic photodiodes arranged in four pixel columns are connected to four readout lines.

In some embodiments, the display panel further includes: a multiplexer configured to connect the four readout lines to one sensing channel.

In some embodiments, each of the plurality of sensing pixel circuits includes: a first transistor configured to apply a reset voltage to a gate node in response to a reset signal; a second transistor configured to generate a sensing current based on a voltage of the gate node; a third transistor configured to transfer the sensing current to a readout line in response to a scan signal; a fourth transistor configured to connect an anode of a first organic photodiode of the plurality of organic photodiodes to the gate node in response to a first transfer signal; and a fifth transistor configured to connect an anode of a second organic photodiode of the plurality of organic photodiodes to the gate node in response to a second transfer signal.

According to some embodiments of the present disclosure, there is provided a display device including: a display panel including a plurality of light emitting pixels, a plurality of organic photodiodes and a plurality of sensing pixel circuits; a data driver configured to provide data signals to the plurality of light emitting pixels; a scan driver configured to provide scan signals to the plurality of light emitting pixels and the plurality of sensing pixel circuits; and a readout circuit connected to the plurality of sensing pixel circuits through a plurality of readout lines, wherein one of the plurality of organic photodiodes is arranged per four light emitting pixels of the plurality of light emitting pixels, and wherein two organic photodiodes of the plurality of organic photodiodes are connected to one sensing pixel circuit of the plurality of sensing pixel circuits.

In some embodiments, each of the plurality of sensing pixel circuits includes: a first transistor configured to apply a reset voltage to a gate node in response to a reset signal; a second transistor configured to generate a sensing current based on a voltage of the gate node; a third transistor configured to transfer the sensing current to a readout line in response to a scan signal; a fourth transistor configured to connect an anode of a first organic photodiode of the plurality of organic photodiodes to the gate node in response to a first transfer signal; and a fifth transistor configured to connect an anode of a second organic photodiode of the plurality of organic photodiodes to the gate node in response to a second transfer signal.

According to some embodiments of the present disclosure, there is provided an electronic device including the display device as described above.

In some embodiments, the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

As described above, in a light sensing pixel, a display panel and a display device according to some embodiments, two organic photodiodes may be connected to one sensing pixel circuit. Further, anode extensions of the two organic photodiodes may have substantially the same length to the sensing pixel circuit. Accordingly, a resolution of the display panel may be improved, and a light sensing accuracy may be improved.

### BRIEF DESCRIPTION OF THE DRAWINGS

Illustrative, non-limiting embodiments will be more clearly understood from the following detailed description in conjunction with the accompanying drawings.

FIG. 1 is a circuit diagram illustrating a light sensing pixel according to some embodiments of the present disclosure.

FIG. 2 is a timing diagram for describing an operation of a light sensing pixel according to some embodiments of the present disclosure.

FIG. 3 is a circuit diagram for describing an operation of a light sensing pixel of FIG. 1 in a first frame period, according to some embodiments of the present disclosure.

FIG. 4 is a circuit diagram for describing an operation of a light sensing pixel of FIG. 1 in a second frame period, according to some embodiments of the present disclosure.

FIG. 5 is a circuit diagram for describing an operation of a light sensing pixel of FIG. 1 in a third frame period, according to some embodiments of the present disclosure.

FIG. 6 is a circuit diagram for describing an operation of a light sensing pixel of FIG. 1 in a fourth frame period, according to some embodiments of the present disclosure.

FIG. 7 is a circuit diagram for describing an operation of a light sensing pixel of FIG. 1 in a fifth frame period, according to some embodiments of the present disclosure.

FIG. 8 is a circuit diagram for describing an operation of a light sensing pixel of FIG. 1 in a sixth frame period, according to some embodiments of the present disclosure.

FIG. 9 is a circuit diagram illustrating a light sensing pixel according to some embodiments of the present disclosure.

FIG. 10 is a circuit diagram illustrating a light sensing pixel according to some embodiments of the present disclosure.

FIG. 11 is a diagram illustrating a display panel according to some embodiments of the present disclosure.

FIG. 12 is a diagram illustrating a display panel in which one organic photodiode is connected to one sensing pixel circuit, and two organic photodiodes are connected to one sensing pixel circuit according to some embodiments of the present disclosure.

FIG. 13 is a diagram illustrating a display panel according to some embodiments of the present disclosure.

FIG. 14 is a timing diagram for describing an operation of a display panel of FIG. 13, according to some embodiments of the present disclosure.

FIG. 15 is a diagram illustrating a display panel according to some embodiments of the present disclosure.

FIG. 16 is a diagram illustrating a display panel according to some embodiments of the present disclosure.

FIG. 17 is a diagram illustrating a display panel according to some embodiments of the present disclosure.

FIG. 18 is a timing diagram for describing an operation of a display panel of FIG. 17, according to some embodiments of the present disclosure.

FIG. 19 is a block diagram illustrating a display device according to some embodiments of the present disclosure.

FIG. 20 is a block diagram illustrating an electronic device including a display device according to some embodiments of the present disclosure.

### DETAILED DESCRIPTION

The embodiments are described more fully hereinafter with reference to the accompanying drawings. Like or similar reference numerals refer to like or similar elements throughout.

In the present disclosure, processes, elements, and techniques that are not considered necessary for those having ordinary skill in the art to have a complete understanding of the aspects and features of the present disclosure may not be described or may be only briefly described. In the drawings, the relative sizes of elements, layers, and regions may be exaggerated for clarity.

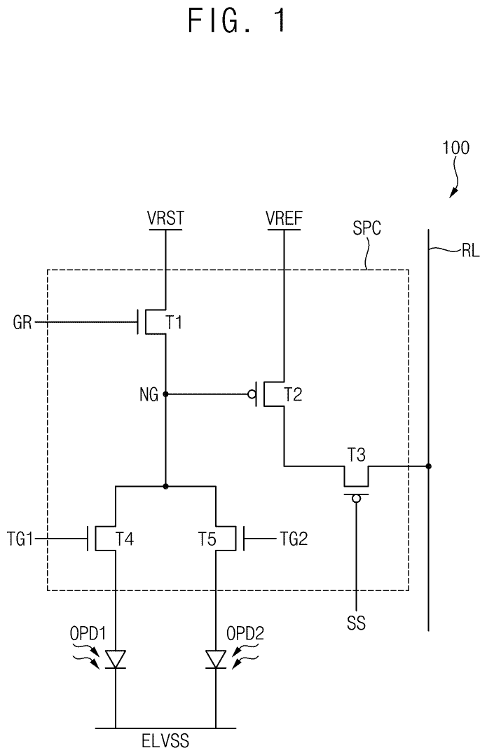

FIG. 1 is a circuit diagram illustrating a light sensing pixel according to some embodiments of the present disclosure.

Referring to FIG. 1, a light sensing pixel 100 according to some embodiments may include a first organic photodiode OPD1, a second organic photodiode OPD2, and a sensing pixel circuit SPC connected to both of the first organic photodiode OPD1 and the second organic photodiode OPD2. In some embodiments, the sensing pixel circuit SPC may include a first transistor T1, a second transistor T2, a third transistor T3, a fourth transistor T4, and a fifth transistor T5.

The first transistor T1 may apply a reset voltage VRST to a gate node NG in response to a reset signal GR. In some embodiments, the reset signal GR may be a global signal that is concurrently or substantially simultaneously applied to all light sensing pixels 100 of a display panel. Further, the reset voltage VRST may be lower than a power supply voltage ELVSS (e.g., a low power supply voltage) and a reference voltage VREF. When the first transistor T1 applies the reset voltage VRST to the gate node NG, and a voltage of the gate node NG may be reset to the reset voltage VRST. In examples in which the fourth transistor T4 is turned on when the first transistor T1 is turned on, an anode voltage of the first organic photodiode OPD1 also may be reset to the reset voltage VRST. Further, in examples in which the fifth transistor T5 is turned on when the first transistor T1 is turned on, an anode voltage of the second organic photodiode OPD2 also may be reset to the reset voltage VRST. In some embodiments, the first transistor T1 may include a gate that receives the reset signal GR, a first terminal connected to a line that transfers the reset voltage VRST, and a second terminal connected to the gate node NG.

The second transistor T2 may generate a sensing current based on a voltage of the gate node NG. For example, when the fourth transistor T4 is turned on, and the gate node NG is connected to an anode of the first organic photodiode OPD1, the second transistor T2 may generate a sensing current based on the anode voltage of the first organic photodiode OPD1. Furthermore, when the fifth transistor T5 is turned on, and the gate node NG is connected to an anode of the second organic photodiode OPD2, the second transistor T2 may generate a sensing current based on the anode voltage of the second organic photodiode OPD2. In some embodiments, the second transistor T2 may include a gate connected to the gate node NG, a first terminal connected to a line which transfers the reference voltage VREF, and a second terminal. In some embodiments, the reference voltage VREF may have a voltage level substantially the same as a voltage level of the power supply voltage ELVSS, but is not limited thereto.

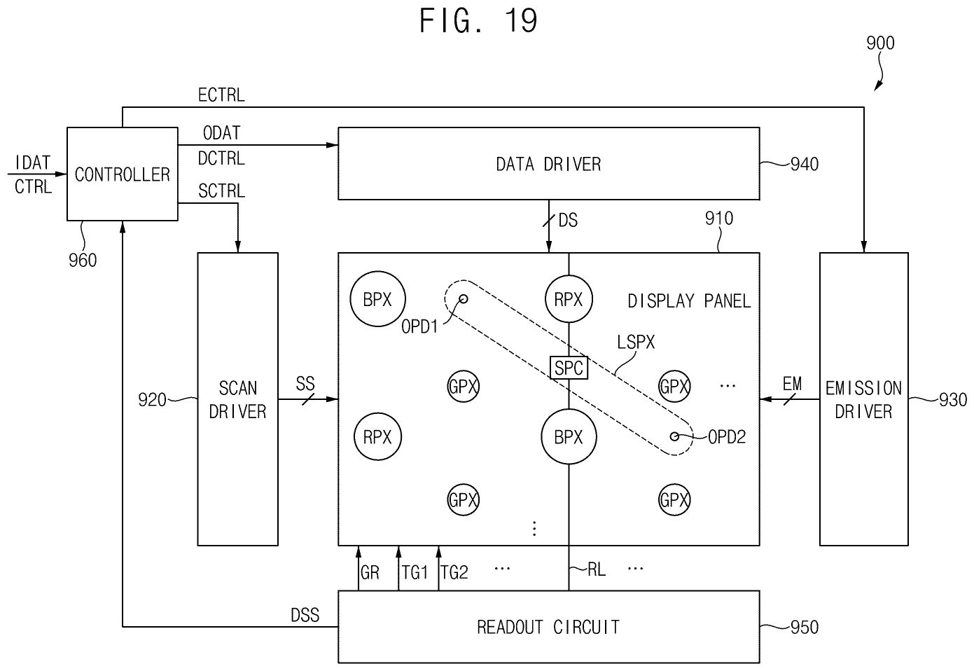

The third transistor T3 may connect the second terminal of the second transistor T2 to a readout line RL in response to a scan signal SS. Thus, when the third transistor T3 is turned on, the sensing current generated by the second transistor T2 may be provided to a readout circuit 950 illustrated in FIG. 19 through the readout line RL. In some embodiments, the scan signal SS may be a scan signal SS applied to light emitting pixels included in the display panel. Further, in some embodiments, the third transistor T3 may include a gate that receives the scan signal SS, a first terminal connected to the second terminal of the second transistor T2, and a second terminal connected to the readout line RL.

The fourth transistor T4 may connect the anode of the first organic photodiode OPD1 to the gate node NG in response to a first transfer signal TG1, and the fifth transistor T5 may connect the anode of the second organic photodiode OPD2 to the gate node NG in response to a second transfer signal TG2. Thus, the sensing pixel circuit SPC may perform a light sensing operation using the first organic photodiode OPD1 in response to the first transfer signal TG1. That is, while the first transfer signal TG1 is at an active level (also referred to as an activation or turn-on level; e.g., a high level), the anode of the first organic photodiode OPD1 may be connected to the gate node NG, and the sensing current corresponding to an intensity of light applied to (e.g., light incident on) the first organic photodiode OPD1 may be output through the readout line RL. Further, the sensing pixel circuit SPC may perform a light sensing operation using the second organic photodiode OPD2 in response to the second transfer signal TG2. That is, while the second transfer signal TG2 is at an active level, the anode of the second organic photodiode OPD2 may be connected to the gate node NG, and the sensing current corresponding to an intensity of light applied to (e.g., light incident on) the second organic photodiode OPD2 may be output through the readout line RL. In some embodiments, the fourth transistor T4 may include a gate that receives the first transfer signal TG1, a first terminal connected to the gate node NG, and a second terminal connected to the anode of the first organic photodiode OPD1, and the fifth transistor T5 may include a gate that receives the second transfer signal TG2, a first terminal connected to the gate node NG, and a second terminal connected to the anode of the second organic photodiode OPD2.

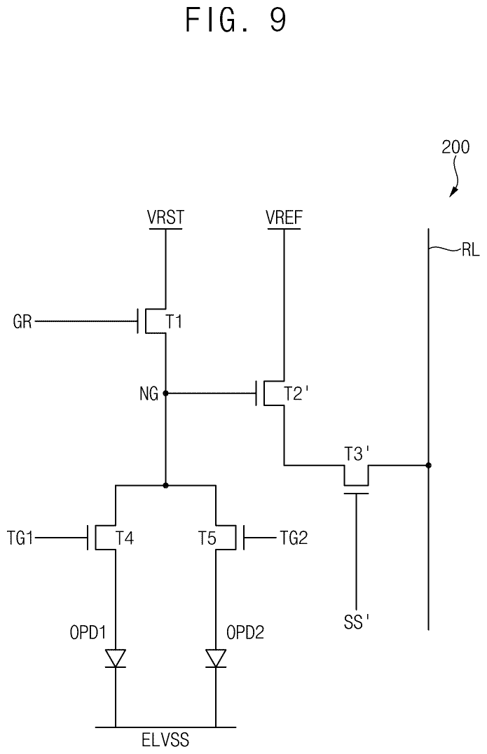

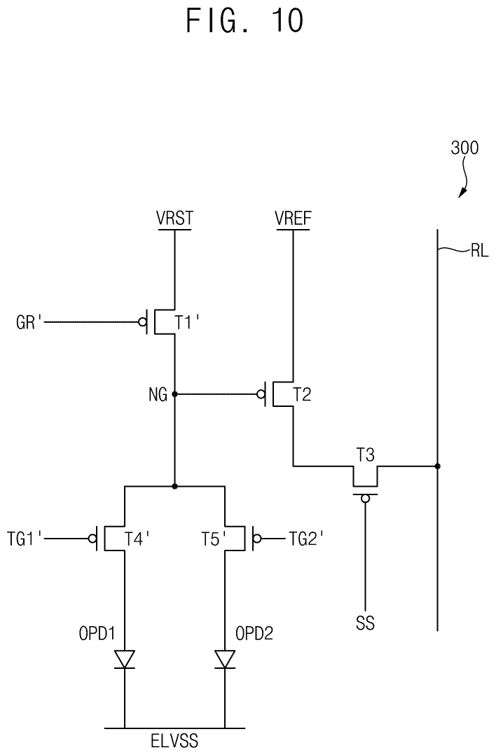

In some embodiments, as illustrated in FIG. 1, the second and third transistors T2 and T3 may be P-type metal-oxide-semiconductor (“PMOS”) transistors, and the first, fourth, and fifth transistors T1, T4, and T5 may be N-type metal-oxide-semiconductor (“NMOS”) transistors, but are not limited thereto. In some other embodiments, as described below with reference to FIG. 9, all of the first, second, third, fourth, and fifth transistors T1, T2′, T3′, T4, and T5 may be NMOS transistors. In still other embodiments, as described below with reference to FIG. 10, all of the first, second, third, fourth, and fifth transistors T1′, T2, T3, T4′, and T5′ may be PMOS transistors. In still other embodiments, any of the first through fifth transistors T1 through T5 may be PMOS transistors, and the remaining transistors may be NMOS transistors.

The first and second organic photodiodes OPD1 and OPD2 may be used to measure the light intensity. For example, while the anode of the first organic photodiode OPD1 is connected to the gate node NG, the anode voltage of the first organic photodiode OPD1 may be reset to the reset voltage VRST, and then may change according to the intensity of light applied to (e.g., incident on) the first organic photodiode OPD1. In such examples, the sensing pixel circuit SPC may output the sensing current corresponding to the intensity of light applied to (e.g., incident on) the first organic photodiode OPD1 based on the anode voltage of the first organic photodiode OPD1. Further, while the anode of the second organic photodiode OPD2 is connected to the gate node NG, the anode voltage of the second organic photodiode OPD2 may be reset to the reset voltage VRST, and then may change according to the intensity of light applied to (e.g., incident on) the second organic photodiode OPD2. In such examples, the sensing pixel circuit SPC may output the sensing current corresponding to the intensity of light applied to (e.g., incident on) the second organic photodiode OPD2 based on the anode voltage of the second organic photodiode OPD2. In some embodiments, the first organic photodiode OPD1 may include the anode connected to the second terminal of the fourth transistor T4, and a cathode connected to a line which transfers the power supply voltage ELVSS, and the second organic photodiode OPD2 may include the anode connected to the second terminal of the fifth transistor T5, and a cathode connected to the line which the power supply voltage ELVSS. In some embodiments, the power supply voltage ELVSS may be the low power supply voltage ELVSS for the light emitting pixels included in the display panel.

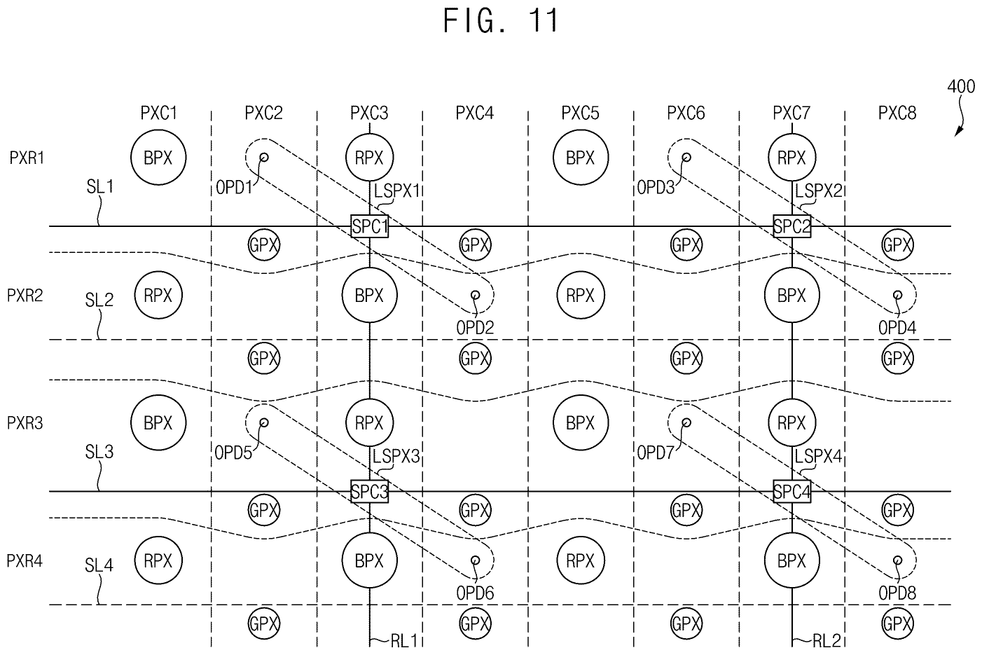

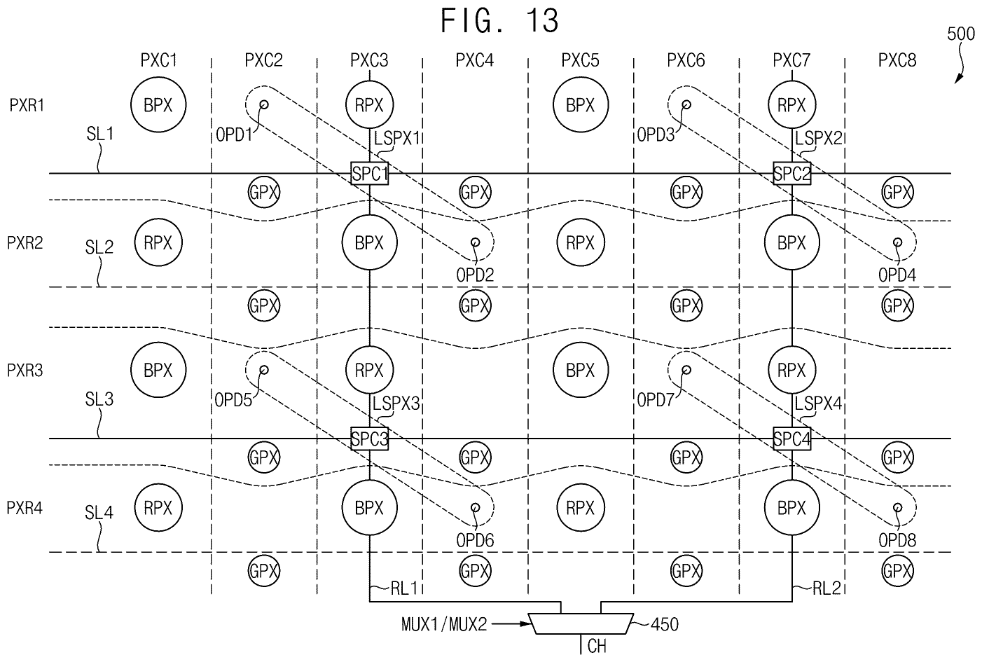

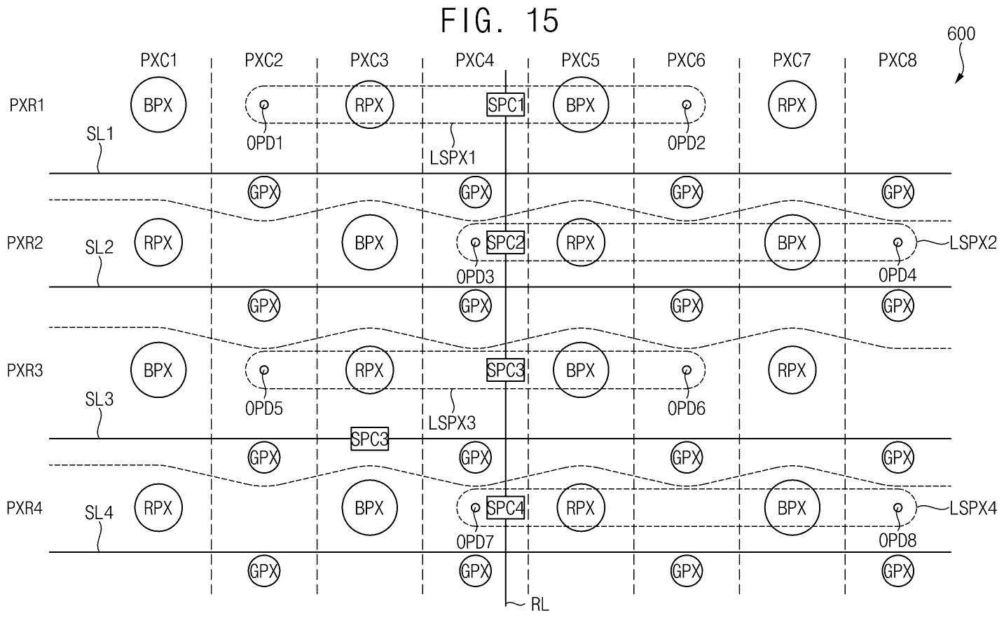

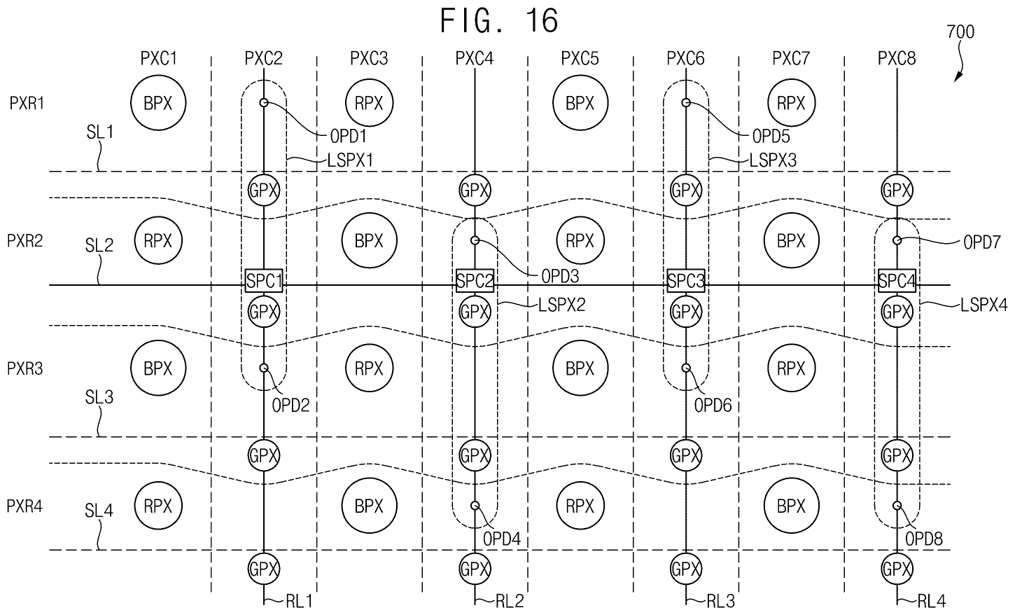

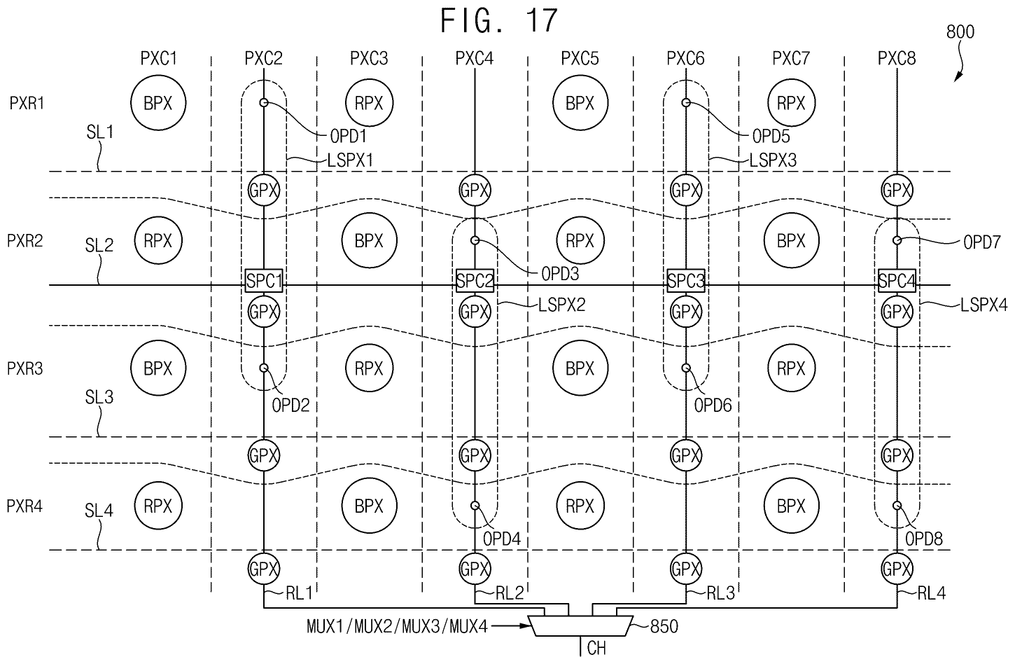

In some embodiments, as described below with reference to FIGS. 11 and 13, the first organic photodiode OPD1 and the second organic photodiode OPD2 may be arranged in different pixel rows and different pixel columns. In some other embodiments, as described below with reference to FIG. 15, the first organic photodiode OPD1 and the second organic photodiode OPD2 may be arranged in the same pixel row and different pixel columns. In still other embodiments, as described below with reference to FIGS. 16 and 17, the first organic photodiode OPD1 and the second organic photodiode OPD2 may be arranged in different pixel rows and the same pixel column.

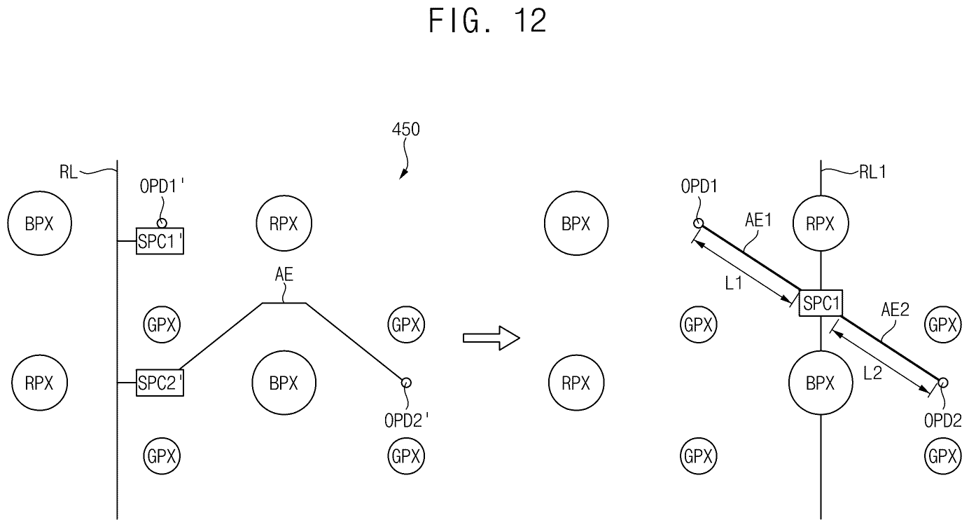

In a display device according to some embodiments, two organic photodiodes OPD1 and OPD2 may be connected to the single sensing pixel circuit SPC, and the single sensing pixel circuit SPC may drive the two organic photodiodes OPD1 and OPD2. As described below with reference to FIG. 12, in a display panel in which respective organic photodiodes OPD1′ and OPD2′ are connected to different sensing pixel circuits SPC1′ and SPC2′, the organic photodiodes OPD1′ and OPD2′ may have anode extensions AE (see, e.g., FIG. 12) having different lengths. However, in the display device according to some embodiments, the first and second organic photodiodes OPD1 and OPD2 may be connected to the same sensing pixel circuit SPC, and a length L1 of an anode extension AE1 (see, e.g., FIG. 12) of the first organic photodiode OPD1 to the sensing pixel circuit SPC may be substantially equal to a length L2 of an anode extension AE2 (see, e.g., FIG. 12) of the second organic photodiode OPD2 to the sensing pixel circuit SPC. Accordingly, in the display device according to some embodiments, because the two organic photodiodes OPD1 and OPD2 are driven by the single sensing pixel circuit SPC, a resolution of the display panel may be improved (e.g., increased). Further, in the display device according to some embodiments, because the anode extensions AE1 and AE2 (see, e.g., FIG. 12) of the first and second organic photodiodes OPD1 and OPD2 have substantially the same length L1 and L2, a light sensing accuracy may be improved.

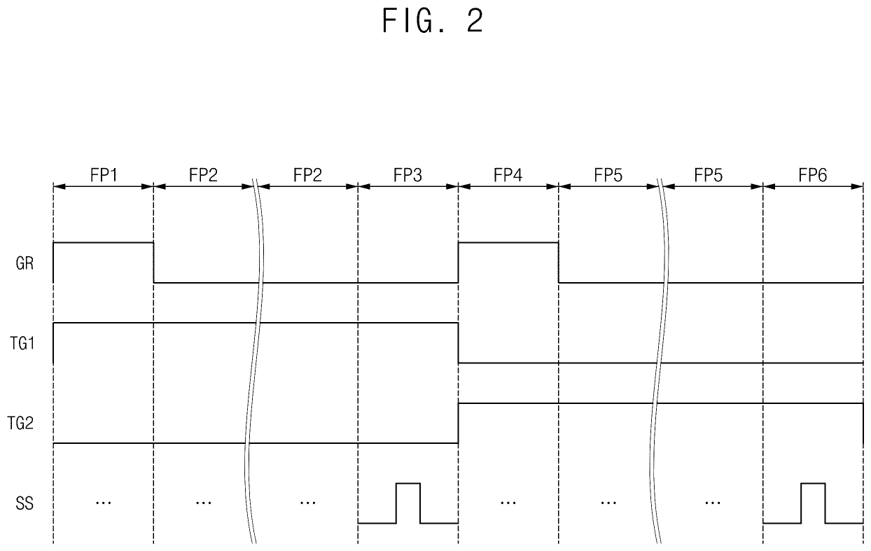

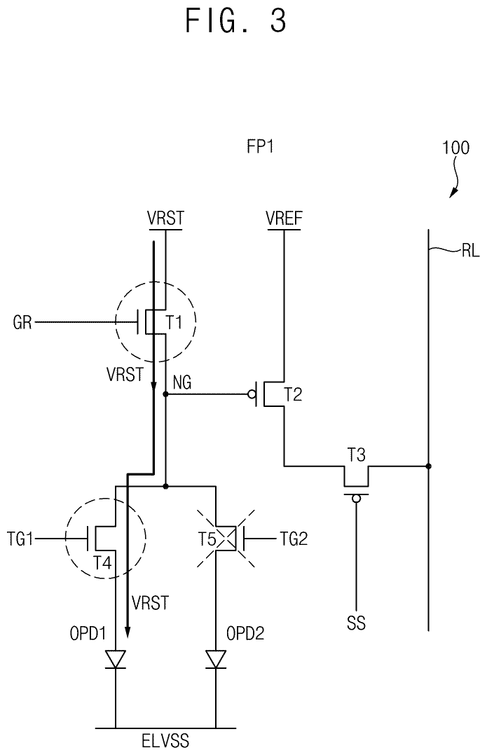

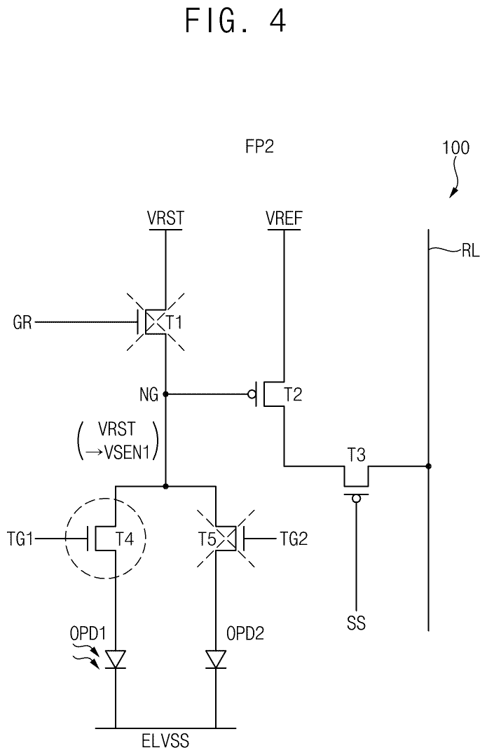

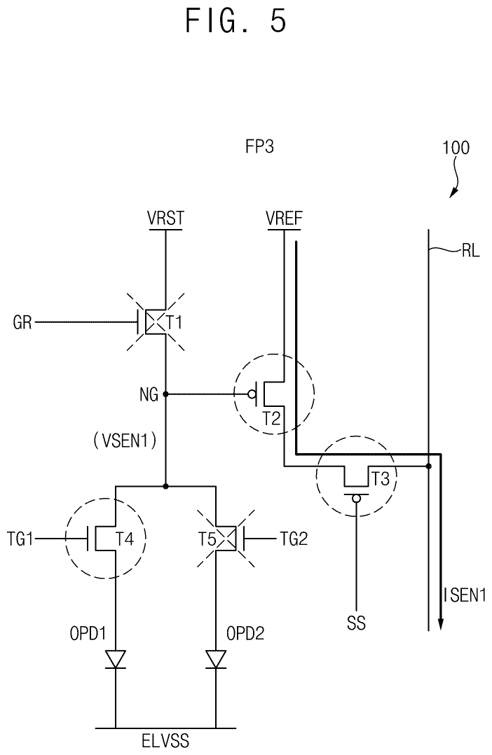

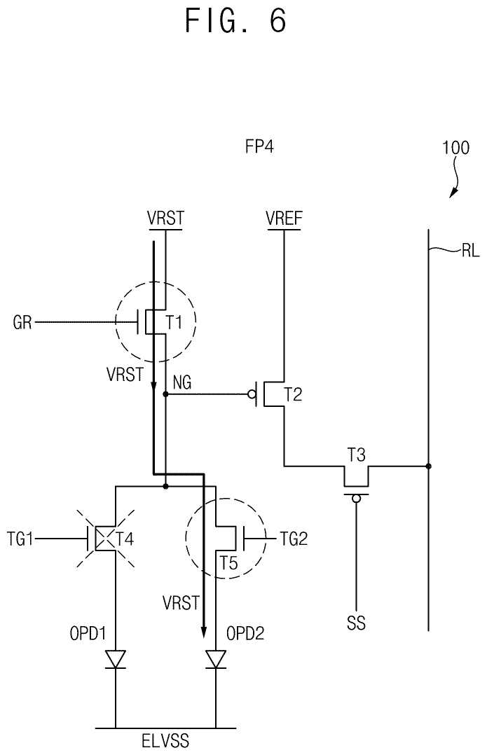

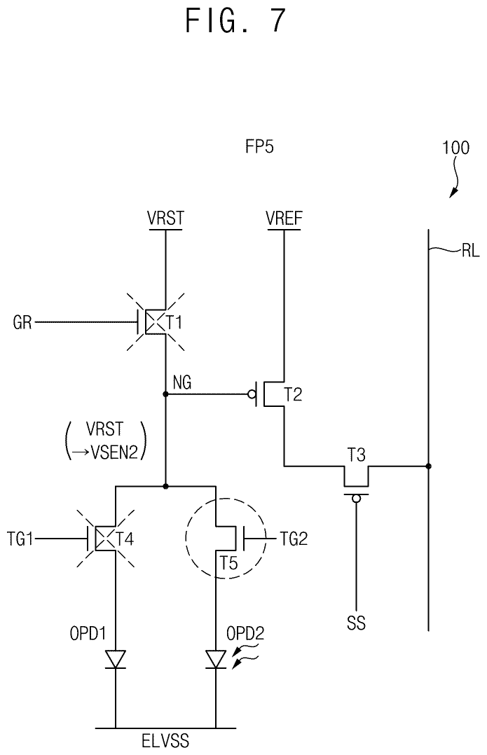

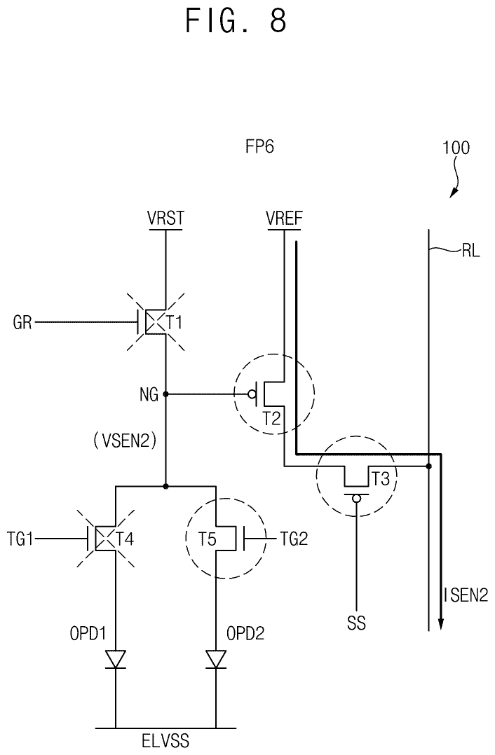

FIG. 2 is a timing diagram for describing an operation of a light sensing pixel according to some embodiments of the present disclosure; FIG. 3 is a circuit diagram for describing an operation of a light sensing pixel of FIG. 1 in a first frame period, according to some embodiments of the present disclosure; FIG. 4 is a circuit diagram for describing an operation of a light sensing pixel of FIG. 1 in a second frame period, according to some embodiments of the present disclosure; FIG. 5 is a circuit diagram for describing an operation of a light sensing pixel of FIG. 1 in a third frame period, according to some embodiments of the present disclosure; FIG. 6 is a circuit diagram for describing an operation of a light sensing pixel of FIG. 1 in a fourth frame period, according to some embodiments of the present disclosure; FIG. 7 is a circuit diagram for describing an operation of a light sensing pixel of FIG. 1 in a fifth frame period, according to some embodiments of the present disclosure; FIG. 8 is a circuit diagram for describing an operation of a light sensing pixel of FIG. 1 in a sixth frame period, according to some embodiments of the present disclosure; FIG. 9 is a circuit diagram illustrating a light sensing pixel according to some embodiments of the present disclosure; and FIG. 10 is a circuit diagram illustrating a light sensing pixel according to some embodiments of the present disclosure.

Referring to FIGS. 1 and 2, in first through third frame periods FP1 through FP3, the first transfer signal TG1 may be at the active level (e.g., the high level), the anode of the first organic photodiode OPD1 may be connected to the gate node NG, and the light sensing operation using the first organic photodiode OPD1 may be performed.

In the first frame period FP1, the voltage of the gate node NG and the anode voltage of the first organic photodiode OPD1 may be reset to the reset voltage VRST. In some embodiments, the first frame period FP1 may be referred to as a first reset period. For example, as illustrated in FIG. 3, the first transistor T1 may be turned on in response to the reset signal GR being at the active level, the fourth transistor T4 may be turned on in response to the first transfer signal TG1 being at the active level, and the fifth transistor T5 may be turned off in response to the second transfer signal TG2 being at the inactive level (also referred to as a deactivation or turn-off level; e.g., the low level). The first transistor T1 may apply the reset voltage VRST to the gate node NG, and thus the voltage of the gate node NG may be reset to the reset voltage VRST. Further, the fourth transistor T4 may connect the anode of the first organic photodiode OPD1 to the gate node NG, and thus the anode voltage of the first organic photodiode OPD1 also may be reset to the reset voltage VRST.

In one or more second frame periods FP2, the anode voltage of the first organic photodiode OPD1 and the voltage of the gate node NG may be changed according to the intensity of light applied to (e.g., incident on) the first organic photodiode OPD1. In some embodiments, the second frame periods FP2 may be referred to as first exposure and integration periods. For example, as illustrated in FIG. 4, the fourth transistor T4 may be turned on in response to the first transfer signal TG1 1 being at the active level, and may connect the anode of the first organic photodiode OPD1 to the gate node NG. Further, the first and fifth transistors T1 and T5 may be turned off. During the one or more second frame periods FP2, when light is applied to (e.g., incident on) the first organic photodiode OPD1, the anode voltage of the first organic photodiode OPD1 may be changed to a first sensing voltage VSEN1 corresponding to the intensity of light applied to (e.g., incident on) the first organic photodiode OPD1. For example, when the intensity of light applied to (e.g., incident on) the first organic photodiode OPD1 is relatively high, the anode voltage of the first organic photodiode OPD1 may be increased to the first sensing voltage VSEN1 having a relatively high voltage level. Further, when the intensity of light applied to (e.g., incident on) the first organic photodiode OPD1 is relatively low, the anode voltage of the first organic photodiode OPD1 may be increased to the first sensing voltage VSEN1 having a relatively low voltage level. In addition, because the anode of the first organic photodiode OPD1 is connected to the gate node NG, the voltage of the gate node NG also may be changed to the first sensing voltage VSEN1 corresponding to the intensity of light applied to (e.g., incident on) the first organic photodiode OPD1.

In the third frame period FP3, the sensing current corresponding to the voltage of the gate node NG, or the sensing current corresponding to the anode voltage of the first organic photodiode OPD1, may be output to the readout line RL. In some embodiments, the third frame period FP3 may be referred to as a first readout period. For example, as illustrated in FIG. 5, the second transistor T2 may generate a first sensing current ISEN1 based on the voltage of the gate node NG, or the first sensing voltage VSEN1 corresponding to the intensity of light applied to (e.g., incident on) the first organic photodiode OPD1. Thus, an amount of the first sensing current ISEN1 may be determined according to the intensity of light applied to (e.g., incident on) the first organic photodiode OPD1. For example, when the intensity of light applied to (e.g., incident on) the first organic photodiode OPD1 is relatively high, the first sensing voltage VSEN1 may be relatively high, and the first sensing current ISEN1 may be relatively small. Further, when the intensity of light applied to (e.g., incident on) the first organic photodiode OPD1 is relatively low, the first sensing voltage VSEN1 may be relatively low, and the first sensing current ISEN1 may be relatively large. The third transistor T3 may be turned on in response to the scan signal SS being at the active level (e.g., the low level), and may output the first sensing current ISEN1 generated by the second transistor T2 to the readout line RL. In some embodiments, the scan signal SS may be sequentially applied on a pixel row basis, and the first sensing currents ISEN1 of the light sensing pixels 100 of the display panel may be sequentially output on the pixel row basis. Furthermore, the readout circuit 950 illustrated in FIG. 19 may receive the first sensing current ISEN1 through the readout line RL, and may generate a digital sensing signal DSS corresponding to the first sensing current ISEN1. In addition, in the third frame period FP3, as illustrated in FIG. 5, the first and fifth transistors T1 and T5 may be turned off, and the fourth transistor T4 may be maintained in a turned-on state (e.g., in an active state). In some other embodiments, in the third frame period FP3, the first transfer signal TG1 may be at the inactive level, and the fourth transistor T4 also may be turned off.

Further, in fourth through sixth frame periods FP4 through FP6, the second transfer signal TG2 may be at the active level (e.g., the high level), the anode of the second organic photodiode OPD2 may be connected to the gate node NG, and the light sensing operation using the second organic photodiode OPD2 may be performed.

In the fourth frame period FP4, the voltage of the gate node NG and the anode voltage of the second organic photodiode OPD2 may be reset to the reset voltage VRST. In some embodiments, the fourth frame period FP4 may be referred to as a second reset period. For example, as illustrated in FIG. 6, the first transistor T1 may be turned on in response to the reset signal GR being at the active level, the fifth transistor T5 may be turned on in response to the second transfer signal TG2 being at the active level, and the fourth transistor T4 may be turned off in response to the first transfer signal TG1 being at the inactive level (e.g., the low level). The first transistor T1 may apply the reset voltage VRST to the gate node NG, and thus the voltage of the gate node NG may be reset to the reset voltage VRST. Further, the fifth transistor T5 may connect the anode of the second organic photodiode OPD2 to the gate node NG, and thus the anode voltage of the second organic photodiode OPD2 also may be reset to the reset voltage VRST.

In one or more fifth frame periods FP5, the anode voltage of the second organic photodiode OPD2 and the voltage of the gate node NG may be changed according to the intensity of light applied to (e.g., incident on) the second organic photodiode OPD2. In some embodiments, the fifth frame periods FP5 may be referred to as second exposure and integration periods. For example, as illustrated in FIG. 7, the fifth transistor T5 may be turned on in response to the second transfer signal TG2 being at the active level, and may connect the anode of the second organic photodiode OPD2 to the gate node NG. Further, the first and fourth transistors T1 and T4 may be turned off. During the one or more fifth frame periods FP5, when light is applied to (e.g., incident on) the second organic photodiode OPD2, the anode voltage of the second organic photodiode OPD2 may be changed to a second sensing voltage VSEN2 corresponding to the intensity of light applied to (e.g., incident on) the second organic photodiode OPD2. For example, when the intensity of light applied to (e.g., incident on) the second organic photodiode OPD2 is relatively high, the anode voltage of the second organic photodiode OPD2 may be increased to the second sensing voltage VSEN2 having a relatively high voltage level. When the intensity of light applied to (e.g., incident on) the second organic photodiode OPD2 is relatively low, the anode voltage of the second organic photodiode OPD2 may be increased to the second sensing voltage VSEN2 having a relatively low voltage level. Furthermore, because the anode of the second organic photodiode OPD2 is connected to the gate node NG, the voltage of the gate node NG also may be changed to the second sensing voltage VSEN2 corresponding to the intensity of light applied to (e.g., incident on) the second organic photodiode OPD2.

In the sixth frame period FP6, the sensing current corresponding to the voltage of the gate node NG, or the sensing current corresponding to the anode voltage of the second organic photodiode OPD2, may be output to the readout line RL. In some embodiments, the sixth frame period FP6 may be referred to as a second readout period. For example, as illustrated in FIG. 8, the second transistor T2 may generate a second sensing current ISEN2 based on the voltage of the gate node NG, or the second sensing voltage VSEN2 corresponding to the intensity of light applied to (e.g., incident on) the second organic photodiode OPD2. Thus, an amount of the second sensing current ISEN2 may be determined according to the intensity of light applied to (e.g., incident on) the second organic photodiode OPD2. For example, when the intensity of light applied to (e.g., incident on) the second organic photodiode OPD2 is relatively high, the second sensing voltage VSEN2 may be relatively high, and the second sensing current ISEN2 may be relatively small. Further, when the intensity of light applied to (e.g., incident on) the second organic photodiode OPD2 is relatively large, the second sensing voltage VSEN2 may be relatively low, and the second sensing current ISEN2 may be relatively large. The third transistor T3 may be turned on in response to the scan signal SS being at the active level (e.g., the low level), and may output the second sensing current ISEN2 generated by the second transistor T2 to the readout line RL. In some embodiments, the scan signal SS may be sequentially applied on a pixel row basis, and the second sensing currents ISEN2 of the light sensing pixels 100 of the display panel may be sequentially output on the pixel row basis. Furthermore, the readout circuit 950 illustrated in FIG. 19 may receive the second sensing current ISEN2 through the readout line RL, and may generate the digital sensing signal DSS corresponding to the second sensing current ISEN2. In addition, in the sixth frame period FP6, as illustrated in FIG. 8, the first and fourth transistors T1 and T4 may be turned off, and the fifth transistor T5 may be maintained in the turned-on state. In some other embodiments, in the sixth frame period FP6, the second transfer signal TG2 may be at the inactive level, and the fifth transistor T5 also may be turned off.

As described above, during the first through third frame periods FP1 through FP3, the first transfer signal TG1 may be at the active level, and the light sensing operation using the first organic photodiode OPD1 may be performed. Further, during the fourth through sixth frame periods FP4 through FP6, the second transfer signal TG2 may be at the active level, and the light sensing operation using the second organic photodiode OPD2 may be performed.

FIG. 9 is a circuit diagram illustrating a light sensing pixel according to some embodiments of the present disclosure.

Referring to FIG. 9, a light sensing pixel 200 according to some embodiments may include a first organic photodiode OPD1, a second organic photodiode OPD2, a first transistor T1, a second transistor T2′, a third transistor T3′, a fourth transistor T4, and a fifth transistor T5. The light sensing pixel 200 of FIG. 9 may have substantially the same configuration and substantially the same operational function as a pixel 100 of FIG. 1, except that the second and third transistors T2′ and T3′ are implemented as NMOS transistors.

The second transistor T2′ may generate a sensing current based on a voltage of a gate node NG. As the voltage of the gate node NG increases, an amount of the sensing current generated by the second transistor T2′ implemented as the NMOS transistor may increase. Further, the third transistor T3′ may connect the second transistor T2′ to a readout line RL in response to a scan signal SS′. The scan signal SS′ may have a high level as an active level, and may have a low level as an inactive level. The scan signal SS′ having the high level may be sequentially applied on a pixel row basis.

FIG. 10 is a circuit diagram illustrating a light sensing pixel according to some embodiments of the present disclosure.

Referring to FIG. 10, a light sensing pixel 300 according to some embodiments may include a first organic photodiode OPD1, a second organic photodiode OPD2, a first transistor T1′, a second transistor T2, a third transistor T3, a fourth transistor T4′, and a fifth transistor T5′. The light sensing pixel 300 of FIG. 10 may have substantially the same configuration and substantially the same operational function as a pixel 100 of FIG. 1, except that the first, fourth, and fifth transistors T1′, T4′, and T5′ are implemented as PMOS transistors.

The first transistor T1′ may apply a reset voltage VRST to a gate node NG in response to a reset signal GR′, the fourth transistor T4′ may connect an anode of the first organic photodiode OPD1 to the gate node NG in response to a first transfer signal TG1′, and the fifth transistor T5′ may connect an anode of the second organic photodiode OPD2 to the gate node NG in response to a second transfer signal TG2′.

The reset signal GR′, the first transfer signal TG1′ and the second transfer signal TG2′ may have a low level as an active level, and may have a high level as an inactive level.

Although FIG. 1 illustrates an example in which the second and third transistors T2 and T3 are PMOS transistors and the first, fourth and fifth transistors T1, T4 and T5 are NMOS transistors, FIG. 9 illustrates an example in which all of the first, second, third, fourth, and fifth transistors T1, T2′, T3′, T4, and T5 are NMOS transistors, and FIG. 10 illustrates an example in which all of the first, second, third, fourth, and fifth transistors T1′, T2, T3, T4′, and T5′ are PMOS transistors, a light sensing pixel according to some embodiments is not limited to the examples of FIG. 1, FIG. 9, and FIG. 10.

FIG. 11 is a diagram illustrating a display panel according to some embodiments of the present disclosure; and FIG. 12 is a diagram illustrating a display panel in which one organic photodiode is connected to one sensing pixel circuit, and two organic photodiodes are connected to one sensing pixel circuit according to some embodiments of the present disclosure.

Referring to FIG. 11, a display panel 400 according to some embodiments may include a plurality of light emitting pixels RPX, GPX, and BPX, a plurality of organic photodiodes OPD1, OPD2, OPD3, OPD4, OPD5, OPD6, OPD7, and OPD8, and a plurality of sensing pixel circuits SPC1, SPC2, SPC3, and SPC4. Although FIG. 11 illustrates an example of the display panel 400 having four pixel rows PXR1, PXR2, PXR3, and PXR4 and eight pixel columns PXC1, PXC2, PXC3, PXC4, PXC5, PXC6, PXC7, and PXC8 for convenience of explanation, the display panel 400 according to some embodiments is not limited to the examples of FIG. 11. According to some embodiments, the display panel 400 may include four or more pixel rows and eight or more pixel columns.

In some embodiments, as illustrated in FIG. 11, a blue light emitting pixel BPX, a green light emitting pixel GPX, a red light emitting pixel RPX, and a green light emitting pixel GPX may be sequentially arranged in each odd-numbered pixel row PXR1 and PXR3, and a red light emitting pixel RPX, a green light emitting pixel GPX, a blue light emitting pixel BPX, and a green light emitting pixel GPX may be sequentially arranged in each even-numbered pixel row PXR2 and PXR4. In some other embodiments, a red light emitting pixel RPX, a green light emitting pixel GPX, a blue light emitting pixel BPX, and a green light emitting pixel GPX may be sequentially arranged in each odd-numbered pixel row PXR1 and PXR3, and a blue light emitting pixel BPX, a green light emitting pixel GPX, a red light emitting pixel RPX, and a green light emitting pixel GPX may be sequentially arranged in each even-numbered pixel row PXR2 and PXR4. Further, in some embodiments, as illustrated in FIG. 11, blue light emitting pixels BPX, and red light emitting pixels RPX may be alternately arranged in each odd-numbered pixel column PXC1, PXC3, PXC5, and PXC7, and green light emitting pixels GPX may be arranged in each even-numbered pixel column PXC2, PXC4, PXC6, and PXC8. However, the pixel arrangement according to some embodiments is not limited to the examples of FIG. 11.

In the display panel 400 according to some embodiments, one organic photodiode may be arranged per four light emitting pixels RPX, GPX, and BPX. For example, in each pixel row (e.g., in a first pixel row PXR1), four light emitting pixels RPX, GPX, and BPX may be arranged in four consecutive pixel columns (e.g., first, second, third, and fourth pixel columns PXC1, PXC2, PXC3, and PXC4), and one organic photodiode (e.g., a first organic photodiode OPD1) may be arranged in one (e.g., the second pixel column PXC2) of the four consecutive pixel columns. Further, in some embodiments, as illustrated in FIG. 11, one blue light emitting pixel BPX, two green light emitting pixels GPX and one red light emitting pixel RPX may be arranged in a diamond shape, and one organic photodiode may be arranged at the center of the diamond shape.

Further, in the display panel 400 according to some embodiments, two organic photodiodes may be connected to one sensing pixel circuit, and the two organic photodiodes and the one sensing pixel circuit may form one light sensing pixel.

For example, a first organic photodiode OPD1 located in a first pixel row PXR1 and a second pixel column PXC2 may be connected to a first sensing pixel circuit SPC1 located in the first pixel row PXR1 and a third pixel column PXC3; a second organic photodiode OPD2 located in a second pixel row PXR2 and a fourth pixel column PXC4 may be connected to the same first sensing pixel circuit SPC1; and the first and second organic photodiodes OPD1 and OPD2 and the first sensing pixel circuit SPC1 may form a first light sensing pixel LSPX1. Further, a third organic photodiode OPD3 located in the first pixel row PXR1 and a sixth pixel column PXC6 may be connected to a second sensing pixel circuit SPC2 located in the first pixel row PXR1 and a seventh pixel column PXC7; a fourth organic photodiode OPD4 located in the second pixel row PXR2 and an eighth pixel column PXC8 may be connected to the same second sensing pixel circuit SPC2; and the third and fourth organic photodiodes OPD3 and OPD4 and the second sensing pixel circuit SPC2 may form a second light sensing pixel LSPX2. Further, a fifth organic photodiode OPD5 located in a third pixel row PXR3 and the second pixel column PXC2 may be connected to a third sensing pixel circuit SPC3 located in the third pixel row PXR3 and the third pixel column PXC3; a sixth organic photodiode OPD6 located in a fourth pixel row PXR4 and the fourth pixel column PXC4 may be connected to the same third sensing pixel circuit SPC3; and the fifth and sixth organic photodiodes OPD5 and OPD6 and the third sensing pixel circuit SPC3 may form a third light sensing pixel LSPX3. Furthermore, a seventh organic photodiode OPD7 located in the third pixel row PXR3 and the sixth pixel column PXC6 may be connected to a fourth sensing pixel circuit SPC4 located in the third pixel row PXR3 and the seventh pixel column PXC7; an eighth organic photodiode OPD8 located in the fourth pixel row PXR4 and the eighth pixel column PXC8 may be connected to the same fourth sensing pixel circuit SPC4; and the seventh and eighth organic photodiodes OPD7 and OPD8 and the fourth sensing pixel circuit SPC4 may form a fourth light sensing pixel LSPX4.

As illustrated in FIG. 12, in a display panel 450 in which respective organic photodiodes OPD1′ and OPD2′ are connected to different sensing pixel circuits SPC1′ and SPC2′, a first organic photodiode OPD1′ located in a first pixel row may have no anode extension or an anode extension having a relatively short length, but a second organic photodiode OPD2′ located in a second pixel row may have an anode extension AE having a relatively long length. Thus, in the display panel 450 in which the respective organic photodiodes OPD1′ and OPD2′ are connected to the different sensing pixel circuits SPC1′ and SPC2′, the organic photodiodes OPD1′ and OPD2′ may have anode extensions AE having different lengths. However, in the display panel 400 according to some embodiments, because the first and second organic photodiodes OPD1 and OPD2 respectively located in the second and fourth pixel columns PXC2 and PXC4 are connected to the same first sensing pixel circuit SPC1 arranged in the third pixel column PXC3 between the second and fourth pixel columns PXC2 and PXC4, a length L1 of an anode extension AE1 of the first organic photodiode OPD1 to the first sensing pixel circuit SPC1 may be substantially the same as a length L2 of an anode extension AE2 of the second organic photodiode OPD2 to the first sensing pixel circuit SPC1. Accordingly, in the display panel 400 according to some embodiments, because the anode extensions AE1 and AE2 of the two organic photodiodes OPD1 and OPD2 connected to the one sensing pixel circuit SPC1 have the same length L1 and L2 to the one sensing pixel circuit SPC1, a light sensing accuracy may be improved (e.g., increased). Further, in the display panel 400 according to some embodiments, because the two organic photodiodes OPD1 and OPD2 are driven by the single sensing pixel circuit SPC1, a resolution of the display panel 400 may be improved (e.g., increased).

Referring again to FIG. 11, in the display panel 400, the plurality of sensing pixel circuits SPC1, SPC2, SPC3, and SPC4 connected to the plurality of organic photodiodes OPD1, OPD2, OPD3, OPD4, OPD5, OPD6, OPD7, and OPD8 arranged in four consecutive pixel rows PXR1, PXR2, PXR3, and PXR4 may be connected to two scan lines SL1 and SL3 among four scan lines SL1, SL2, SL3, and SL4 arranged in the four consecutive pixel rows PXR1, PXR2, PXR3, and PXR4. For example, the first and second sensing pixel circuits SPC1 and SPC2 may be connected to a first scan line SL1, the third and fourth sensing pixel circuits SPC3 and SPC4 may be connected to a third scan line SL3, and second and fourth scan lines SL2 and SL4 may not be connected to sensing pixel circuits. Further, the plurality of sensing pixel circuits SPC1, SPC2, SPC3, and SPC4 connected to the plurality of organic photodiodes OPD1, OPD2, OPD3, OPD4, OPD5, OPD6, OPD7, and OPD8 arranged in four pixel columns, or the second, fourth, sixth, and eighth pixel columns PXC2, PXC4, PXC6, and PXC8, may be connected to two readout lines RL1 and RL2. For example, the first and third sensing pixel circuits SPC1 and SPC3 may be connected to a first readout line RL1, and the second and fourth sensing pixel circuits SPC2 and SPC4 may be connected to a second readout line RL2. In some embodiments, the first and second readout lines RL1 and RL2 of the display panel 400 may be connected to two sensing channels of a readout circuit 950 illustrated in FIG. 19, respectively.

As described above, in the display panel 400 according to some embodiments, the two organic photodiodes may be connected to the one sensing pixel circuit. Accordingly, the anode extensions of the two organic photodiodes may have substantially the same length to the sensing pixel circuit, the resolution of the display panel 400 may be improved (e.g., increased), and the light sensing accuracy may be improved (e.g., increased).

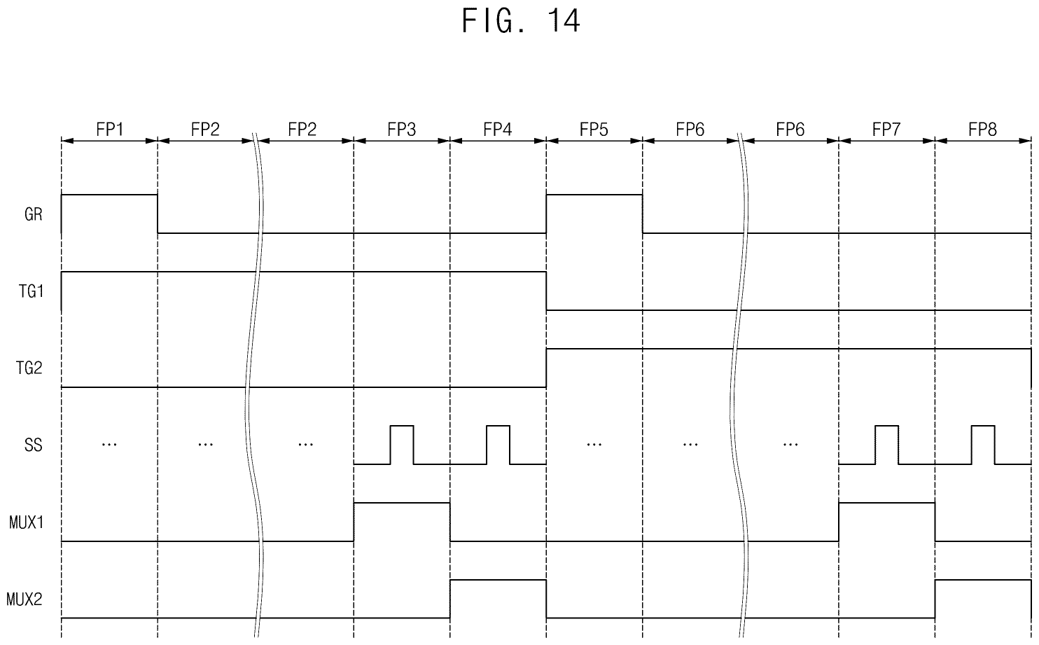

FIG. 13 is a diagram illustrating a display panel according to some embodiments of the present disclosure. FIG. 14 is a timing diagram for describing an operation of a display panel of FIG. 13, according to some embodiments of the present disclosure.

Referring to FIG. 13, a display panel 500 according to some embodiments may include a plurality of light emitting pixels RPX, GPX, and BPX, a plurality of organic photodiodes OPD1, OPD2, OPD3, OPD4, OPD5, OPD6, OPD7, and OPD8, a plurality of sensing pixel circuits SPC1, SPC2, SPC3, and SPC4, and a multiplexer 550. The display panel 500 of FIG. 13 may have substantially the same configuration as a display panel 400 of FIG. 11, except that the display panel 500 may further include the multiplexer 550.

The multiplexer 550 may selectively connect a first readout line RL1 or a second readout line RL2 to a sensing channel CH of a readout circuit 950 illustrated in FIG. 19 in response to a first multiplex signal MUX1 and a second multiplex signal MUX2. In some embodiments, the multiplexer 550 may connect the first readout line RL1 to the sensing channel CH in response to the first multiplex signal MUX1 being at an active level, and may connect the second readout line RL2 to the sensing channel CH in response to the second multiplex signal MUX2 being at an active level.

Referring to FIGS. 13 and 14, in first through fourth frame periods FP1 through FP4, a first transfer signal TG1 may be at an active level (e.g., a high level), and a light sensing operation using first, third, fifth and seventh organic photodiodes OPD1, OPD3, OPD5, and OPD7 may be performed. In the first frame period FP1, anode voltages of the first, third, fifth and seventh organic photodiodes OPD1, OPD3, OPD5, and OPD7 may be reset to a reset voltage. In one or more second frame periods FP2, the anode voltages of the first, third, fifth and seventh organic photodiodes OPD1, OPD3, OPD5, and OPD7 may be changed according to a light intensity. In a third frame period FP3, the first multiplex signal MUX1 is at the active level (e.g., the high level), the multiplexer 550 may connect the first readout line RL1 to the sensing channel CH, and the sensing channel CH of the readout circuit 950 illustrated in FIG. 19 may convert sensing currents for the first and fifth organic photodiodes OPD1 and OPD5 into a digital sensing signal DSS. Further, in the fourth frame period FP4, the second multiplex signal MUX2 may be at the active level, the multiplexer 550 may connect the second readout line RL2 to the sensing channel CH, and the sensing channel CH of the readout circuit 950 illustrated in FIG. 19 may convert sensing currents for the third and seventh organic photodiodes OPD3 and OPD7 into the digital sensing signal DSS.

In addition, in fifth through eighth frame periods FP5 through FP8, a second transfer signal TG2 is at an active level, and a light sensing operation using second, fourth, sixth and eighth organic photodiodes OPD2, OPD4, OPD6, and OPD8 may be performed. In the fifth frame period FP5, anode voltages of the second, fourth, sixth and eighth organic photodiodes OPD2, OPD4, OPD6, and OPD8 may be reset to the reset voltage. In one or more sixth frame periods FP6, the anode voltages of the second, fourth, sixth and eighth organic photodiodes OPD2, OPD4, OPD6, and OPD8 may be changed according to the light intensity. In a seventh frame period FP7, the first multiplex signal MUX1 may be at the active level, the multiplexer 550 may connect the first readout line RL1 to the sensing channel CH, and the sensing channel CH of the readout circuit 950 illustrated in FIG. 19 may convert sensing currents for the second and sixth organic photodiodes OPD2 and OPD6 into the digital sensing signal DSS. Further, in the eighth frame period FP8, the second multiplex signal MUX2 may be at the active level, the multiplexer 550 may connect the second readout line RL2 to the sensing channel CH, and the sensing channel CH of the readout circuit 950 illustrated in FIG. 19 may convert sensing currents for the fourth and eighth organic photodiodes OPD4 and OPD8 into the digital sensing signal DSS.

FIG. 15 is a diagram illustrating a display panel according to some embodiments of the present disclosure.

Referring to FIG. 15, a display panel 600 according to some embodiments may include a plurality of light emitting pixels RPX, GPX, and BPX, a plurality of organic photodiodes OPD1, OPD2, OPD3, OPD4, OPD5, OPD6, OPD7, and OPD8, and a plurality of sensing pixel circuits SPC1, SPC2, SPC3, and SPC4.

In the display panel 600 of FIG. 15, two organic photodiodes arranged in the same pixel row may be connected to one sensing pixel circuit. For example, in a first pixel row PXR1, a first organic photodiode OPD1 located in a second pixel column PXC2 and a second organic photodiode OPD2 located in a sixth pixel column PXC6 may be connected to a first sensing pixel circuit SPC1, and the first and second organic photodiodes OPD1 and OPD2 and the first sensing pixel circuit SPC1 may form a first light sensing pixel LSPX1. Further, in a second pixel row PXR2, a third organic photodiode OPD3 located in a fourth pixel column PXC4 and a fourth organic photodiode OPD4 located in an eighth pixel column PXC8 may be connected to a second sensing pixel circuit SPC2, and the third and fourth organic photodiodes OPD3 and OPD4 and the second sensing pixel circuit SPC2 may form a second light sensing pixel LSPX2. Further, in a third pixel row PXR3, a fifth organic photodiode OPD5 located in the second pixel column PXC2 and a sixth organic photodiode OPD6 located in the sixth pixel column PXC6 may be connected to a third sensing pixel circuit SPC3, and the fifth and sixth organic photodiodes OPD5 and OPD6 and the third sensing pixel circuit SPC3 may form a third light sensing pixel LSPX3. Furthermore, in a fourth pixel row PXR4, a seventh organic photodiode OPD7 located in the fourth pixel column PXC4, and an eighth organic photodiode OPD8 located in the eighth pixel column PXC8 may be connected to a fourth sensing pixel circuit SPC4, and the seventh and eighth organic photodiodes OPD7 and OPD8 and the fourth sensing pixel circuit SPC4 may form a fourth light sensing pixel LSPX4.

In addition, in the display panel 600, the plurality of sensing pixel circuits SPC1, SPC2, SPC3, and SPC4 connected to the plurality of organic photodiodes OPD1, OPD2, OPD3, OPD4, OPD5, OPD6, OPD7, and OPD8 arranged in four consecutive pixel rows PXR1, PXR2, PXR3, and PXR4 may be connected to four scan lines SL1, SL2, SL3, and SL4 arranged in the four consecutive pixel rows PXR1, PXR2, PXR3, and PXR4. For example, a first sensing pixel circuit SPC1 may be connected to a first scan line SL1, a second sensing pixel circuit SPC2 may be connected to a second scan line SL2, a third sensing pixel circuit SPC3 may be connected to a third scan line SL3, and a fourth sensing pixel circuit SPC4 may be connected to a fourth scan line SL4. Further, the plurality of sensing pixel circuits SPC1, SPC2, SPC3, and SPC4 connected to the plurality of organic photodiodes OPD1, OPD2, OPD3, OPD4, OPD5, OPD6, OPD7, and OPD8 arranged in four pixel columns, or the second, fourth, sixth, and eighth pixel columns PXC2, PXC4, PXC6, and PXC8, may be connected to one readout line RL.

FIG. 16 is a diagram illustrating a display panel according to some embodiments of the present disclosure.

Referring to FIG. 16, a display panel 700 according to some embodiments may include a plurality of light emitting pixels RPX, GPX, and BPX, a plurality of organic photodiodes OPD1, OPD2, OPD3, OPD4, OPD5, OPD6, OPD7, and OPD8, and a plurality of sensing pixel circuits SPC1, SPC2, SPC3, and SPC4.

In the display panel 700 of FIG. 16, two organic photodiodes arranged in the same pixel column may be connected to one sensing pixel circuit. For example, in a second pixel column PXC2, a first organic photodiode OPD1 located in a first pixel row PXR1 and a second organic photodiode OPD2 located in a third pixel row PXR3 may be connected to a first sensing pixel circuit SPC1, and the first and second organic photodiodes OPD1 and OPD2 and the first sensing pixel circuit SPC1 may form a first light sensing pixel LSPX1. Further, in a second pixel column PXC2, a third organic photodiode OPD3 located in a second pixel row PXR2 and a fourth organic photodiode OPD4 located in a fourth pixel row PXR4 may be connected to a second sensing pixel circuit SPC2, and the third and fourth organic photodiodes OPD3 and OPD4 and the second sensing pixel circuit SPC2 may form a second light sensing pixel LSPX2. Further, in a sixth pixel column PXC6, a fifth organic photodiode OPD5 located in the first pixel row PXR1 and a sixth organic photodiode OPD6 located in the third pixel row PXR3 may be connected to a third sensing pixel circuit SPC3, and the fifth and sixth organic photodiodes OPD5 and OPD6 and the third sensing pixel circuit SPC3 may form a third light sensing pixel LSPX3. Furthermore, in an eighth pixel column PXC8, a seventh organic photodiode OPD7 located in the second pixel row PXR2 and an eighth organic photodiode OPD8 located in the fourth pixel row PXR4 may be connected to a fourth sensing pixel circuit SPC4, and the seventh and eighth organic photodiodes OPD7 and OPD8 and the fourth sensing pixel circuit SPC4 may form a fourth light sensing pixel LSPX4.

In addition, in the display panel 700, the plurality of sensing pixel circuits SPC1, SPC2, SPC3, and SPC4 connected to the plurality of organic photodiodes OPD1, OPD2, OPD3, OPD4, OPD5, OPD6, OPD7, and OPD8 arranged in four consecutive pixel rows PXR1, PXR2, PXR3, and PXR4 may be connected to one scan line SL2 of four scan lines SL1, SL2, SL3, and SL4 arranged in the four consecutive pixel rows PXR1, PXR2, PXR3, and PXR4. For example, the first, second, third, and fourth sensing pixel circuits SPC1, SPC2, SPC3, and SPC4 may be connected to a second scan line SL2, and first, third, and fourth scan lines SL1, SL3, and SL4 may not be connected to sensing pixel circuits. Further, the plurality of sensing pixel circuits SPC1, SPC2, SPC3, and SPC4 connected to the plurality of organic photodiodes OPD1, OPD2, OPD3, OPD4, OPD5, OPD6, OPD7, and OPD8 arranged in four pixel columns, or the second, fourth, sixth and eighth pixel columns PXC2, PXC4, PXC6, and PXC8, may be connected to four readout lines RL1, RL2, RL3, and RL4. For example, the first sensing pixel circuit SPC1 may be connected to a first readout line RL1, the second sensing pixel circuit SPC2 may be connected to a second readout line RL2, the third sensing pixel circuit SPC3 may be connected to a third readout line RL3, and the fourth sensing pixel circuit SPC4 may be connected to a fourth readout line RL4. In some embodiments, the first, second, third, and fourth readout lines RL1, RL2, RL3, and RL4 of the display panel 700 may be connected to four sensing channels of a readout circuit 950 illustrated in FIG. 19, respectively.

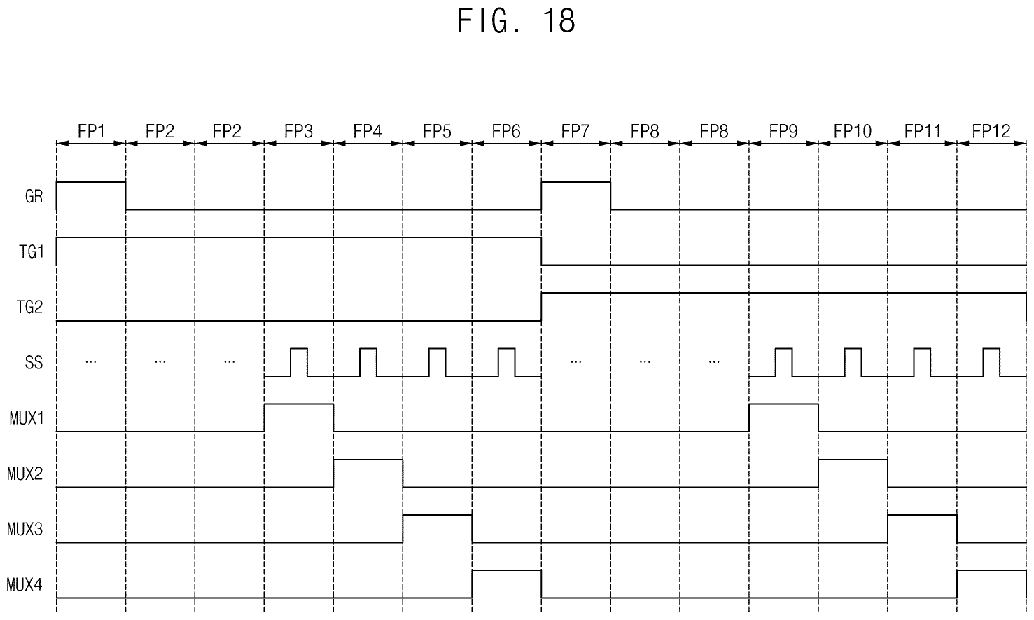

FIG. 17 is a diagram illustrating a display panel according to some embodiments of the present disclosure; and FIG. 18 is a timing diagram for describing an operation of a display panel of FIG. 17, according to some embodiments of the present disclosure.

Referring to FIG. 17, a display panel 800 according to some embodiments may include a plurality of light emitting pixels RPX, GPX, and BPX, a plurality of organic photodiodes OPD1, OPD2, OPD3, OPD4, OPD5, OPD6, OPD7, and OPD8, a plurality of sensing pixel circuits SPC1, SPC2, SPC3, and SPC4, and a multiplexer 850. The display panel 800 of FIG. 17 may have substantially the same configuration as a display panel 700 of FIG. 16, except that the display panel 800 may further include the multiplexer 850.

The multiplexer 850 may selectively connect a first readout line RL1, a second readout line RL2, a third readout line RL3, or a fourth readout line RL4 to a sensing channel CH of a readout circuit 950 illustrated in FIG. 19 in response to a first multiplex signal MUX1, a second multiplex signal MUX2, a third multiplex signal MUX3, and a fourth multiplex signal MUX4. In some embodiments, the multiplexer 850 may connect the first readout line RL1 to the sensing channel CH in response to the first multiplex signal MUX1 being at an active level, may connect the second readout line RL2 to the sensing channel CH in response to the second multiplex signal MUX2 being at an active level, may connect the third readout line RL3 to the sensing channel CH in response to the third multiplex signal MUX3 being at an active level, and may connect the fourth readout line RL4 to the sensing channel CH in response to the fourth multiplex signal MUX4 being at an active level.

Referring to FIGS. 17 and 18, in first through sixth frame periods FP1 through FP6, a first transfer signal TG1 may be at an active level (e.g., a high level), and a light sensing operation using the first, third, fifth, and seventh organic photodiodes OPD1, OPD3, OPD5, and OPD7 may be performed. In the first frame period FP1, anode voltages of the first, third, fifth, and seventh organic photodiodes OPD1, OPD3, OPD5, and OPD7 may be reset to a reset voltage. In one or more second frame periods FP2, the anode voltages of the first, third, fifth, and seventh organic photodiodes OPD1, OPD3, OPD5, and OPD7 may be changed according to a light intensity. In a third frame period FP3, the first multiplex signal MUX1 is at the active level (e.g., the high level), the multiplexer 850 may connect the first readout line RL1 to the sensing channel CH, and the sensing channel CH of the readout circuit 950 illustrated in FIG. 19 may convert a sensing current for the first organic photodiode OPD1 into a digital sensing signal DSS. In addition, in a fourth frame period FP4, the second multiplex signal MUX2 may be at the active level, the multiplexer 850 may connect the second readout line RL2 to the sensing channel CH, and the sensing channel CH of the readout circuit 950 illustrated in FIG. 19 may convert a sensing current for the third organic photodiode OPD3 into the digital sensing signal DSS. In a fifth frame period FP5, the third multiplex signal MUX3 may be at the active level, the multiplexer 850 may connect the third readout line RL3 to the sensing channel CH, and the sensing channel CH of the readout circuit 950 illustrated in FIG. 19 may convert a sensing current for the fifth organic photodiode OPD5 into the digital sensing signal DSS. Further, in the sixth frame period FP6, the fourth multiplex signal MUX4 may be at the active level, the multiplexer 850 may connect the fourth readout line RL4 to the sensing channel CH, and the sensing channel CH of the readout circuit 950 illustrated in FIG. 19 may convert a sensing current for the seventh organic photodiode OPD7 into the digital sensing signal DSS.

In addition, in seventh through twelfth frame periods FP7 through FP12, a second transfer signal TG2 may be at an active level, and a light sensing operation using the second, fourth, sixth, and eighth organic photodiodes OPD2, OPD4, OPD6, and OPD8 may be performed. In the seventh frame period FP7, anode voltages of the second, fourth, sixth, and eighth organic photodiodes OPD2, OPD4, OPD6, and OPD8 may be reset to the reset voltage. In one or more eighth frame periods FP8, the anode voltages of the second, fourth, sixth, and eighth organic photodiodes OPD2, OPD4, OPD6, and OPD8 may be changed according to the light intensity. In a ninth frame period FP9, the first multiplex signal MUX1 may be at the active level, the multiplexer 850 may connect the first readout line RL1 to the sensing channel CH, and the sensing channel CH of the readout circuit 950 illustrated in FIG. 19 may convert a sensing current for the second organic photodiode OPD2 into the digital sensing signal DSS. Further, in a tenth frame period FP10, the second multiplex signal MUX2 may be at the active level, the multiplexer 850 may connect the second readout line RL2 to the sensing channel CH, and the sensing channel CH of the readout circuit 950 illustrated in FIG. 19 may convert a sensing current for the fourth organic photodiode OPD4 into the digital sensing signal DSS. Further, in an eleventh frame period FP11, the third multiplex signal MUX3 may be at the active level, the multiplexer 850 may connect the third readout line RL3 to the sensing channel CH, and the sensing channel CH of the readout circuit 950 illustrated in FIG. 19 may convert a sensing current for the sixth organic photodiode OPD6 into the digital sensing signal DSS. Furthermore, in the twelfth frame period FP12, the fourth multiplex signal MUX4 may be at the active level, the multiplexer 850 may connect the fourth readout line RL4 to the sensing channel CH, and the sensing channel CH of the readout circuit 950 illustrated in FIG. 19 may convert a sensing current for the eighth organic photodiode OPD8 into the digital sensing signal DSS.

FIG. 19 is a block diagram illustrating a display device according to some embodiments of the present disclosure.

Referring to FIG. 19, a display device 900 according to some embodiments may include a display panel 910 that includes a plurality of light emitting pixels RPX, GPX, and BPX and a plurality of light sensing pixels LSPX, a scan driver 920 that provides scan signals SS to the plurality of light emitting pixels RPX, GPX, and BPX and the plurality of light sensing pixels LSPX, an emission driver 930 that provides emission signals EM to the plurality of light emitting pixels RPX, GPX, and BPX, a data driver 940 that provides data signals DS to the plurality of light emitting pixels RPX, GPX, and BPX, a readout circuit 950 connected to the plurality of light sensing pixels LSPX through a plurality of readout lines RL, and a controller 960 that controls an operation of the display device 900.

The display panel 910 may include the plurality of light emitting pixels RPX, GPX, and BPX and the plurality of light sensing pixels LSPX. Each light emitting pixel RPX, GPX, and BPX may include a light emitting element, and may emit light using the light emitting element. For example, the light emitting element may be an organic light emitting diode (“OLED”), a nano light emitting diode (“NED”), a quantum dot (“QD”) light emitting diode, a micro light emitting diode, an inorganic light emitting diode, or any other suitable light emitting element. Each light sensing pixel LSPX may include two organic photodiodes OPD1 and OPD2 and one sensing pixel circuit SPC. The two organic photodiodes OPD1 and OPD2 may be connected to the sensing pixel circuit SPC. The sensing pixel circuit SPC may perform a light sensing operation using a first organic photodiode OPD1 in response to a first transfer signal TG1, and can perform a light sensing operation using a second organic photodiode OPD2 in response to a second transfer signal TG2. In some embodiments, a length of an anode extension of the first organic photodiode OPD1 to the sensing pixel circuit SPC may be substantially the same as a length of an anode extension of the second organic photodiode OPD2 to the sensing pixel circuit SPC. According to some embodiments, the light sensing pixel LSPX may be a light sensing pixel 100 of FIG. 1, a light sensing pixel 200 of FIG. 9 or a light sensing pixel 300 of FIG. 10. Further, according to some embodiments, the display panel 910 may be a display panel 400 of FIG. 11, a display panel 500 of FIG. 13, a display panel 600 of FIG. 15, a display panel 700 of FIG. 16, or a display panel 800 of FIG. 17.

The scan driver 920 may generate the scan signals SS based on a scan control signal SCTRL received from the controller 960, and may sequentially provide the scan signals SS to the plurality of light emitting pixels RPX, GPX, and BPX and the plurality of light sensing pixels LSPX on a pixel row basis. In some embodiments, the scan control signal SCTRL may include, but is not limited to, a scan start signal and a scan clock signal. Furthermore, in some embodiments, the scan driver 920 may be integrated or formed in the display panel 910. In some other embodiments, the scan driver 920 may be implemented with one or more integrated circuits.

The emission driver 930 may generate the emission signals EM based on an emission control signal ECTRL received from the controller 960, and may sequentially provide the emission signals EM to the plurality of light emitting pixels RPX, GPX, and BPX on a pixel row basis. In some embodiments, the emission control signal ECTRL may include, but is not limited to, an emission start signal and an emission clock signal. In some embodiments, the emission driver 930 may be integrated or formed in the display panel 910. In some other embodiments, the emission driver 930 may be implemented with one or more integrated circuits.

The data driver 940 may generate the data signals DS based on a data control signal DCTRL and output image data ODAT received from the controller 960, and may provide the data signals DS to the plurality of light emitting pixels RPX, GPX, and BPX. In some embodiments, the data control signal DCTRL may include, but is not limited to, an output data enable signal, a horizontal start signal, and a load signal. In some embodiments, the data driver 940 and the controller 960 may be implemented as a single integrated circuit, and the single integrated circuit may be referred to as a timing controller embedded data driver (“TED”) integrated circuit. In some other embodiments, the data driver 940 and the controller 960 may be implemented as separate integrated circuits.

The readout circuit 950 may receive sensing currents of the plurality of light sensing pixels LSPX through the plurality of readout lines RL, may generate a digital sensing signal DSS based on the sensing currents, and may provide the digital sensing signal DSS to the controller 960. Further, the readout circuit 950 may concurrently or substantially simultaneously apply a reset signal GR to all the light sensing pixels LSPX of the display panel 910. In addition, the readout circuit 950 may apply the first transfer signal TG1 to the plurality of light sensing pixels LSPX to perform the light sensing operation using the first organic photodiode OPD1, or may apply the second transfer signal TG2 to the plurality of light sensing pixels LSPX to perform the light sensing operation using the second organic photodiode OPD2. In some embodiments, the readout circuit 950 may be implemented as an integrated circuit, and the integrated circuit may be referred to as a readout integrated circuit (“ROIC”). In some other embodiments, the readout circuit 950 may be included in the data driver 940.

The controller 960 (e.g., a timing controller (“TCON”)) may receive input image data IDAT and a control signal CTRL from an external host processor (e.g., a graphics processing unit (“GPU”), an application processor (“AP”) or a graphics card). In some embodiments, the input image data IDAT may be RGB image data including red image data, green image data, and blue image data. In some embodiments, the control signal CTRL may include, but is not limited to, a vertical synchronization signal, a horizontal synchronization signal, an input data enable signal, a master clock signal, etc. The controller 960 may generate the output image data ODAT, the data control signal DCTRL, the scan control signal SCTRL and the emission control signal ECTRL based on the input image data IDAT and the control signal CTRL. The controller 960 may control an operation of the scan driver 920 by providing the scan control signal SCTRL to the scan driver 920, may control an operation of the emission driver 930 by providing the emission control signal ECTRL to the emission driver 930, and may control an operation of the data driver 940 by providing the output image data ODAT and the data control signal DCTRL to the data driver 940.

In the display device 900 according to some embodiments, the two organic photodiodes OPD1 and OPD2 may be connected to the one sensing pixel circuit SPC. Accordingly, the anode extensions of the two organic photodiodes OPD1 and OPD2 may have the same length to the sensing pixel circuit SPC, a resolution of the display panel 910 may be improved, and a light sensing accuracy may be improved.

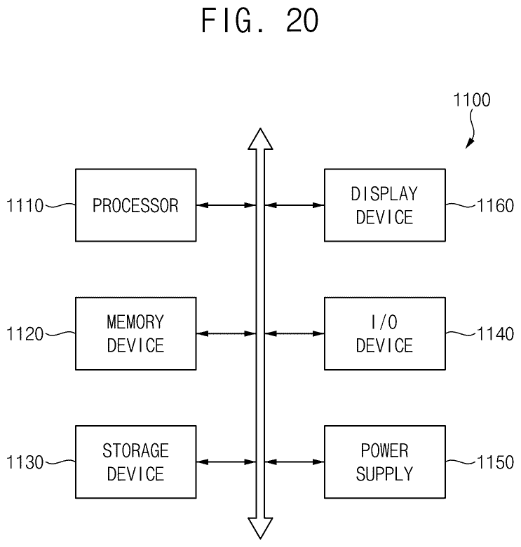

FIG. 20 is a block diagram illustrating an electronic device including a display device according to some embodiments of the present disclosure.

Referring to FIG. 20, an electronic device 1100 may include a processor 1110, a memory device 1120, a storage device 1130, an input/output (I/O) device 1140, a power supply 1150 and a display device 1160. The electronic device 1100 may further include a plurality of ports for communicating with a video card, a sound card, a memory card, a universal serial bus (“USB”) device, and other electric devices, etc.

The processor 1110 may perform various computing functions or tasks. The processor 1110 may be an application processor (“AP”), a micro-processor, a central processing unit (“CPU”), etc. The processor 1110 may be coupled to other components via an address bus, a control bus, a data bus, etc. Further, in some embodiments, the processor 1110 may be further coupled to an extended bus such as a peripheral component interconnection (“PCI”) bus.

The memory device 1120 may store data for operations of the electronic device 1100. For example, the memory device 1120 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, etc., and/or at least one volatile memory device such as a dynamic random access memory (“DRAM”) device, a static random access memory (“SRAM”) device, a mobile dynamic random access memory (“mobile DRAM”) device, etc.

The storage device 1130 may be a solid state drive (“SSD”) device, a hard disk drive (“HDD”) device, a compact disc-read only memory (“CD-ROM”) device, etc. The I/O device 1140 may be an input device such as a keyboard, a keypad, a mouse, a touch screen, etc., and an output device such as a printer, a speaker, etc. The power supply 1150 may supply power for operations of the electronic device 1100. The display device 1160 may be coupled to other components through the buses or other communication links.

In the display device 1160, two organic photodiodes may be connected to one sensing pixel circuit. Further, anode extensions of the two organic photodiodes may have substantially the same length to the sensing pixel circuit. Accordingly, a resolution of the display panel may be improved, and a light sensing accuracy may be improved.

The inventive concepts may be applied any electronic device 1100 including the display device 1160. For example, the inventive concepts may be applied to a mobile phone, a smart phone, a head-mounted display (HMD), a virtual reality (“VR”) device, a television (“TV”) (e.g., a digital TV, a three-dimensional (“3D”) TV, etc.), a wearable electronic device, a personal computer (“PC”) (e.g. a laptop computer, a tablet computer, etc.), a home appliance, a personal digital assistant (“PDA”), an electronic notebook, an electronic book, a portable multimedia player (“PMP”), a digital camera, a music player, a portable game console, a navigation device, an ultra-mobile PC (UMPC), a billboard, an Internet of Things (IOT) device, a smartwatch, a watch phone, etc.

The foregoing is illustrative of embodiments and is not to be construed as limiting thereof. Although a few embodiments have been described, those skilled in the art will readily appreciate that many suitable modifications are possible in the embodiments without materially departing from the novel teachings and advantages of the present inventive concept. Accordingly, all such modifications are intended to be included within the scope of the present inventive concept as defined by the appended claims and their equivalents. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims and their equivalents.

What is claimed is:

1. A light sensing pixel of a display device, the light sensing pixel comprising:
a first organic photodiode;
a second organic photodiode; and
a sensing pixel circuit configured to perform a light sensing operation using the first organic photodiode in response to a first transfer signal, and to perform a light sensing operation using the second organic photodiode in response to a second transfer signal.

2. The light sensing pixel of claim 1, wherein a length of an anode extension of the first organic photodiode to the sensing pixel circuit is equal to a length of an anode extension of the second organic photodiode to the sensing pixel circuit.

3. The light sensing pixel of claim 1, wherein the first organic photodiode and the second organic photodiode are arranged in different pixel rows and different pixel columns on a display panel of the display device.

4. The light sensing pixel of claim 1, wherein the first organic photodiode and the second organic photodiode are arranged in a same pixel row and different pixel columns on a display panel of the display device.

5. The light sensing pixel of claim 1, wherein the first organic photodiode and the second organic photodiode are arranged in different pixel rows and a same pixel column on a display panel of the display device.

6. The light sensing pixel of claim 1, wherein the sensing pixel circuit comprises:
a first transistor configured to apply a reset voltage to a gate node in response to a reset signal;
a second transistor configured to generate a sensing current based on a voltage of the gate node;
a third transistor configured to transfer the sensing current to a readout line in response to a scan signal;
a fourth transistor configured to connect an anode of the first organic photodiode to the gate node in response to the first transfer signal; and
a fifth transistor configured to connect an anode of the second organic photodiode to the gate node in response to the second transfer signal.

7. The light sensing pixel of claim 6, wherein the first transistor comprises a gate configured to receive the reset signal, a first terminal connected to a line configured to transfer the reset voltage, and a second terminal connected to the gate node,
wherein the second transistor comprises a gate connected to the gate node, a first terminal connected to the line configured to transfer a reference voltage, and a second terminal, and
wherein the third transistor comprises a gate configured to receive the scan signal, a first terminal connected to the second terminal of the second transistor, and a second terminal connected to the readout line.

8. The light sensing pixel of claim 6, wherein the fourth transistor comprises a gate configured to receive the first transfer signal, a first terminal connected to the gate node, and a second terminal connected to the anode of the first organic photodiode, and
wherein the fifth transistor comprises a gate configured to receive the second transfer signal, a first terminal connected to the gate node, and a second terminal connected to the anode of the second organic photodiode.

9. The light sensing pixel of claim 6, wherein the second and third transistors are P-type metal-oxide-semiconductor (PMOS) transistors, and
wherein the first, fourth, and fifth transistors are N-type metal-oxide-semiconductor (NMOS) transistors.

10. The light sensing pixel of claim 6, wherein the first through fifth transistors are NMOS transistors.

11. The light sensing pixel of claim 6, wherein the first through fifth transistors are PMOS transistors.

12. The light sensing pixel of claim 6, wherein a voltage of the anode of the first organic photodiode is reset to the reset voltage in a first frame period,
wherein the voltage of the anode of the first organic photodiode is changed according to a light intensity in one or more second frame periods,
wherein the sensing current corresponding to the voltage of the anode of the first organic photodiode is output to the readout line in a third frame period,
wherein a voltage of the anode of the second organic photodiode is reset to the reset voltage in a fourth frame period,
wherein the voltage of the anode of the second organic photodiode is changed according to the light intensity in one or more fifth frame periods,
wherein the sensing current corresponding to the voltage of the anode of the first organic photodiode is output to the readout line in a sixth frame period,
wherein the first transfer signal is at an active level during the first frame period, the one or more second frame periods and the third frame period, and
wherein the second transfer signal is at an active level during the fourth frame period, the one or more fifth frame periods and the sixth frame period.

13. A display panel comprising:
a plurality of light emitting pixels;
a plurality of organic photodiodes; and
a plurality of sensing pixel circuits,
wherein one of the plurality of organic photodiodes is arranged per four light emitting pixels of the plurality of light emitting pixels, and
wherein two organic photodiodes of the plurality of organic photodiodes are connected to one sensing pixel circuit of the plurality of sensing pixel circuits.

14. The display panel of claim 13, wherein anode extensions of the two organic photodiodes connected to the one sensing pixel circuit have a same length to the one sensing pixel circuit.

15. The display panel of claim 13, wherein the plurality of organic photodiodes comprises:
a first organic photodiode arranged in a first pixel row and a second pixel column; and
a second organic photodiode arranged in a second pixel row and a fourth pixel column, and
wherein the first organic photodiode and the second organic photodiode are connected to a same one of the plurality of sensing pixel circuits.

16. The display panel of claim 13, wherein the plurality of organic photodiodes comprises:
a first organic photodiode arranged in a first pixel row and a second pixel column; and
a second organic photodiode arranged in the first pixel row and a sixth pixel column, and
wherein the first organic photodiode and the second organic photodiode are connected to a same one of the plurality of sensing pixel circuits.

17. The display panel of claim 13, wherein the plurality of organic photodiodes comprises:
a first organic photodiode arranged in a first pixel row and a second pixel column; and
a second organic photodiode arranged in a third pixel row and the second pixel column, and
wherein the first organic photodiode and the second organic photodiode are connected to a same one of the plurality of sensing pixel circuits.

18. The display panel of claim 13, wherein each of the plurality of sensing pixel circuits comprises:
a first transistor configured to apply a reset voltage to a gate node in response to a reset signal;
a second transistor configured to generate a sensing current based on a voltage of the gate node;
a third transistor configured to transfer the sensing current to a readout line in response to a scan signal;
a fourth transistor configured to connect an anode of a first organic photodiode of the plurality of organic photodiodes to the gate node in response to a first transfer signal; and
a fifth transistor configured to connect an anode of a second organic photodiode of the plurality of organic photodiodes to the gate node in response to a second transfer signal.

19. An electronic device comprising the display panel of claim 13.

20. The electronic device of claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
